(19) United States
(12) Patent Application Publication
(10) Pub. No.: US 2023/0307589 A1
(43) Pub. Date: Sep. 28, 2023

(54) DISPLAY DEVICE

(71) Applicant: Samsung Display Co., LTD., Yongin-si (KR)

(72) Inventors: Ji Wook MOON, Suwon-si (KR); Byung Choon YANG, Seoul (KR)

(21) Appl. No.: 18/189,066

(22) Filed: Mar. 23, 2023

(30) Foreign Application Priority Data
Mar. 25, 2022 (KR) 10-2022-0037466

(51) Int. Cl. H01L 33/50; H01L 25/075; H01L 27/15

(52) U.S. Cl. CPC H01L 33/504; H01L 25/0753; H01L 27/156

(57) ABSTRACT

A display device includes a substrate including a plurality of sub-pixels; and a plurality of light emitting units provided on the substrate, the plurality of light emitting units respectively corresponding to the plurality of sub-pixels. The plurality of sub-pixels comprises a first sub-pixel corresponding to light of a first color, a second sub-pixel corresponding to light of a second color different from the first color, a third sub-pixel corresponding to light of a third color different from the first color and the second color, and a fourth sub-pixel corresponding to light of a fourth color having a wavelength band wider than those of the first color, the second color, and the third color. One light emitting unit of the plurality of light emitting units comprises a light emitting element and a light adjustment layer covering the light emitting element.

### CROSS-REFERENCE TO RELATED APPLICATION

This application claims priority to and the benefit of Korean Patent Application No. 10-2022-0037466 filed on Mar. 25, 2022, in the Korean Intellectual Property Office, the entire content of which is incorporated herein by reference.

### BACKGROUND

### 1. Field

One or more embodiments of the present disclosure relate to a display device.

### 2. Description of the Related Art

With the advance of information-oriented society, more and more demands are placed on display devices for displaying images in various ways. For example, display devices are employed in various electronic devices such as smartphones, digital cameras, laptop computers, navigation devices, and/or smart televisions.

The display device may be a flat panel display device such as a liquid crystal display, a field emission display and/or a light emitting display.

A light emitting display device may collectively denote an organic light emitting display device including an organic light emitting diode element, an inorganic light emitting display device including an inorganic semiconductor device, and a micro light emitting diode display device including an ultra-small light emitting diode element (or a micro light emitting diode element) depending on light emitting elements emitting light.

### SUMMARY

The display device may display one or more suitable colors including white color, by mixing lights of different colors emitted from two or more adjacent sub-pixels.

However, because white may be displayed only when two or more sub-pixels corresponding to white are all driven, power consumption reduction is limited (e.g., there is a limit on how much power consumption may be reduced).

Further, white light generated by mixing lights of different colors emitted from two or more sub-pixels does not include light of a wavelength band that does not correspond to the two or more sub-pixels, so that white light is unlikely to be similar to sunlight.

Aspects of embodiments of the present disclosure provide a display device capable of reducing power consumption required (or desired) for white display.

Aspects of embodiments of the present disclosure provide a display device capable of displaying white light similar to sunlight.

According to one or more embodiments, a display device may include a substrate including a display area including a plurality of sub-pixels; a plurality of light emitting units on the substrate, the plurality of light emitting units respectively corresponding to the plurality of sub-pixels; and a partition wall on the substrate and corresponding to a boundary between adjacent ones of the plurality of sub-pixels. The plurality of sub-pixels comprises a first sub-pixel corresponding to light of a first color, a second sub-pixel corresponding to light of a second color different from the first color, a third sub-pixel corresponding to light of a third color different from the first color and the second color, and a fourth sub-pixel corresponding to light of a fourth color having a wavelength band wider than wavelength bands of the first color, the second color, and the third color. One light emitting unit of the plurality of light emitting units comprises a light emitting element and a light adjustment layer covering the light emitting element, and the partition wall is around the light emitting unit.

The plurality of light emitting units may include a first light emitting unit corresponding to the first sub-pixel and configured to emit light of the first color; a second light emitting unit corresponding to the second sub-pixel and configured to emit light of the second color; a third light emitting unit corresponding to the third sub-pixel and configured to emit light of the third color; and a fourth light emitting unit corresponding to the fourth sub-pixel and configured to emit light of the fourth color. The first light emitting unit comprises a first light emitting element configured to emit light of the first color, the second light emitting unit comprises a second light emitting element configured to emit light of the second color, the third light emitting unit comprises a third light emitting element configured to emit light of the third color, and the fourth light emitting unit comprises the third light emitting element.

The fourth light emitting unit further may include a phosphor of a fifth color dispersed in the light adjustment layer. The fifth color corresponds to a wavelength band between a wavelength band of the first color and a wavelength band of the second color. The phosphor of the fifth color is configured to convert a part of light of the third color emitted from the third light emitting element into light of the fifth color.

The phosphor of the fifth color may be at least one of (Y,Gd)₃(Al,Ga)₅O₁₂:Ce³⁺ and (Lu,Y)₃(Al,Ga)₅O₁₂:Ce³⁺.

The fourth light emitting unit further may include a phosphor of the first color dispersed in the light adjustment layer together with the phosphor of the fifth color. The phosphor of the first color is configured to convert a part of light of the third color emitted from the third light emitting element into light of the first color.

The phosphor of the fifth color may be at least one of (Y, Gd)₃(Al,Ga)₅O₁₂:Ce³⁺ and (Lu,Y)₃(Al,Ga)₅O₁₂:Ce³⁺. The phosphor of the first color may be (Sr, Ca)AlSiN₃:Eu²⁺.

The fourth light emitting unit further may include a phosphor of the second color dispersed in the light adjustment layer together with the phosphor of the fifth color and the phosphor of the first color. The phosphor of the second color is configured to convert a part of light of the third color emitted from the third light emitting element into light of the second color.

The phosphor of the fifth color may be at least one of (Y, Gd)₃(Al,Ga)₅O₁₂:Ce³⁺, (Lu,Y)₃(Al,Ga)₅O₁₂:Ce³⁺, (Sr, Ba, Mg)SiO₄:Eu²⁺, and (Sr, Ba, Mg)SiO₂N₂:Eu²⁺. The phosphor of the first color may be at least one of (Sr, Ca)AlSiN₃:Eu²⁺, K₂SiF₆:Mn⁴⁺, Na₂SiF₆:Mn⁴⁺, KNaSiF₆:Mn⁴⁺, K₂GeF₆:Mn⁴⁺, K₂TiF₆:Mn⁴⁺, Mg₄GeO₃F:Mn⁴⁺, 3.5MgO·0.5MgF₂·GeO₂:Mn⁴⁺, Sr(Li₂Al₂O₂N₂):Eu²⁺, (Sr, Ba)₂Si₅N₈:Eu²⁺, BaMgAl₁₀O₁₇:Mn⁴⁺, Mg²⁺, CaS:Eu²⁺, InP (QDs), and CsPbI₃ (Perovskite QDs). The phosphor of the second color may be at least one of (Sr, Ba, Mg)₂SiO₄:Eu²⁺, Lu₃(Al,Ga)₅O₁₂:Ce³⁺, Ba₃Si₆O₁₂N₂:Eu²⁺, SrGa₂S₄:Eu²⁺, Gamma AlON:Eu²⁺, InP (QDs), and CsPbBr₃ (QDs)(Perovskite QDs).

The fourth light emitting unit further may include a phosphor of a sixth color dispersed in the light adjustment layer together with the phosphor of the fifth color, the phosphor of the first color, and the phosphor of the second color. The sixth color corresponds to a wavelength band between a wavelength band of the first color and a wavelength band of the fifth color. The phosphor of the sixth color is configured to convert a part of light of the third color emitted from the third light emitting element into light of the sixth color.

The phosphor of the sixth color may be at least one of Alpha-SiAlON and Sr₃SiO₅:Eu²⁺.

The fourth light emitting unit further may include a phosphor of the first color and a phosphor of the second color dispersed in the light adjustment layer. The phosphor of the first color is configured to convert a part of light of the third color emitted from the third light emitting element into light of the first color. The phosphor of the second color is configured to convert a part of light of the third color emitted from the third light emitting element into light of the second color.

The phosphor of the first color may be (Sr, Ca)AlSiN₃:Eu²⁺. The phosphor of the second color may be at least one of Lu₃Al₅O₁₂:Ce³⁺ and Y₃(Al, Ga)₅O₁₂:Ce³⁺.

The fourth light emitting unit further may include a phosphor of a seventh color dispersed in the light adjustment layer together with the phosphor of the first color and the phosphor of the second color. The seventh color corresponds to a wavelength band between a wavelength band of the second color and a wavelength band of the third color. The phosphor of the seventh color is configured to convert a part of light of the third color emitted from the third light emitting element into light of the seventh color.

The phosphor of the first color may be at least one of (Sr, Ca)AlSiN₃:Eu²⁺ and K₂SiF₆:Mn⁴⁺. The phosphor of the second color may be at least one of Lu₃Al₅O₁₂:Ce³⁺ and Y₃(Al, Ga)₅O₁₂:Ce³⁺. The phosphor of the seventh color may be at least one of (Ba, Mg)Si₂O₂N₂:Eu²⁺ and (Ba, Mg)₃Si₆O₃N₈:Eu²⁺.

The plurality of light emitting units may include a first light emitting unit corresponding to the first sub-pixel and configured to emit light of the first color; a second light emitting unit corresponding to the second sub-pixel and configured to emit light of the second color; a third light emitting unit corresponding to the third sub-pixel and configured to emit light of the third color; and a fourth light emitting unit corresponding to the fourth sub-pixel and configured to emit light of the fourth color. The light emitting element of each of the first light emitting unit, the second light emitting unit, the third light emitting unit, and the fourth light emitting unit is configured to emit light of the third color. The first light emitting unit further may include a phosphor of the first color dispersed in a light adjustment layer of the first light emitting unit and configured to convert at least a part of light of the third color emitted from the light emitting element into light of the first color. The second light emitting unit further may include a phosphor of the second color dispersed in a light adjustment layer of the second light emitting unit and configured to convert at least a part of light of the third color emitted from the light emitting element into light of the second color. The fourth light emitting unit further may include a phosphor of a fifth color dispersed in a light adjustment layer of the fourth light emitting unit. The fifth color corresponds to a wavelength band between a wavelength band of the first color and a wavelength band of the second color. The phosphor of the fifth color is configured to convert a part of light of the third color emitted from the light emitting element into light of the fifth color.

The plurality of light emitting units may include a first light emitting unit corresponding to the first sub-pixel and configured to emit light of the first color; a second light emitting unit corresponding to the second sub-pixel and configured to emit light of the second color; a third light emitting unit corresponding to the third sub-pixel and configured to emit light of the third color; and a fourth light emitting unit corresponding to the fourth sub-pixel and configured to emit light of the fourth color. The light emitting element of each of the first light emitting unit, the second light emitting unit, the third light emitting unit, and the fourth light emitting unit configured to emit light of a wavelength band lower than a wavelength band of the third color. The first light emitting unit further may include a phosphor of the first color dispersed in a light adjustment layer of the first light emitting unit and configured to convert at least a part of light emitted from the light emitting element into light of the first color. The second light emitting unit further may include a phosphor of the second color dispersed in a light adjustment layer of the second light emitting unit and configured to convert at least a part of light emitted from the light emitting element into light of the second color. The third light emitting unit further may include a phosphor of the third color dispersed in a light adjustment layer of the third light emitting unit and configured to convert at least a part of light emitted from the light emitting element into light of the third color. The fourth light emitting unit further may include the phosphor of the first color, the phosphor of the second color, and the phosphor of the third color dispersed in a light adjustment layer of the fourth light emitting unit. The phosphor of the first color may be at least one of Mg₄GeO₃F:Mn⁴⁺, 3.5MgO·0.5MgF₂·GeO₂:Mn⁴⁺, K₂(Si, Ge, Ti)SiF₆:Mn⁴⁺, and (Sr, Ca)AlSiN₃:Eu²⁺. The phosphor of the second color may be at least one of Beta-SiAlON:Eu²⁺, SrGa₂S₄:Eu²⁺, BaAlMg₁₀O₁₇:Eu²⁺, Mn²⁺, (Sr, Ba, Mg)₂SiO₄:Eu²⁺, and (Lu,Y)₃(Al, Ga)₅O₁₂:Ce³⁺. The phosphor of the third color may be BaAlMg₁₀O₁₇:Eu²⁺.

The fourth light emitting unit further may include a phosphor of a fifth color and a phosphor of a sixth color dispersed in the light adjustment layer. The fifth color corresponds to a wavelength band between a wavelength band of the first color and a wavelength band of the second color. The phosphor of the fifth color is configured to convert a part of light emitted from the light emitting element into light of the fifth color. The sixth color corresponds to a wavelength band between a wavelength band of the first color and a wavelength band of the fifth color. The phosphor of the sixth color is configured to convert a part of the light emitted from the light emitting element into light of the sixth color. The phosphor of the fifth color may be at least one of (Y, Gd)₃(Al,Ga)₅O₁₂:Ce³⁺ and (Lu,Y)₃(Al,Ga)₅O₁₂:Ce³⁺. The phosphor of the sixth color may be at least one of Alpha-SiAlON and Sr₃SiO₅:Eu²⁺.

An arrangement pattern of the plurality of sub-pixels may include a first pixel column in which a first sub-pixel, a fourth sub-pixel, a third sub-pixel, and a fourth sub-pixel are repeatedly arranged in the first direction; and a second pixel column which alternates with the first pixel column in the second direction intersecting the first direction, and in which a second sub-pixel and a fourth sub-pixel are repeatedly arranged in the first direction. In the second direction, each of the first sub-pixel of the first pixel column and the third sub-pixel of the first pixel column is adjacent to the fourth sub-pixel of the second pixel column. In the second direction, the second sub-pixel of the second pixel column is adjacent to the fourth sub-pixel of the first pixel column.

All (e.g., four) sides of each of the first sub-pixel, the second sub-pixel, and the third sub-pixel may be adjacent to the fourth sub-pixel.

A plurality of pixels each comprising eight sub-pixels adjacent to each other in the first direction and/or the second direction among the plurality of sub-pixels may be provided. Each of the plurality of pixels may include one first sub-pixel, one third sub-pixel, and two fourth sub-pixels adjacent to each other in the first pixel column; and two second sub-pixels and two fourth sub-pixels adjacent to each other in the second pixel column.

An arrangement pattern of the plurality of sub-pixels may include a first pixel column in which the first sub-pixel and the second sub-pixel are alternately arranged side by side in a first direction; a second pixel column in which the second sub-pixel and the third sub-pixel are alternately arranged side by side in the first direction; and a third pixel column in which the fourth sub-pixels are arranged side by side in the first direction. In the second direction intersecting the first direction, the first pixel column and the second pixel column may be adjacent to each other. In the second direction, the first sub-pixel of the first pixel column may be adjacent to the second sub-pixel of the second pixel column, and the third sub-pixel of the second pixel column may be adjacent to the second sub-pixel of the first pixel column. In the second direction, the third pixel column may be between one side of the first pixel column and the other side of the second pixel column.

The fourth sub-pixel of the third pixel column may be adjacent to one second sub-pixel and one third sub-pixel of the second pixel column on one side of the second direction, and may be adjacent to one first sub-pixel and one second sub-pixel of the first pixel column on the other side of the second direction. Each of the first sub-pixel, the second sub-pixel, and the third sub-pixel may have a first width in the first direction. The fourth sub-pixel of the third pixel column may have a second width greater than twice the first width in the first direction.

The first sub-pixel, the second sub-pixel, and the third sub-pixel may have a third width in the second direction. The fourth sub-pixel of the third pixel column may have a fourth width smaller than the third width in the second direction.

A plurality of pixels each comprising five sub-pixels adjacent to each other in the first direction and/or the second direction among the plurality of sub-pixels may be provided. Each of the plurality of pixels may include one first sub-pixel and one second sub-pixel adjacent to each other in the first pixel column; one third sub-pixel and one second sub-pixel adjacent to each other in the second pixel column; and one fourth sub-pixel in the third pixel column.

The fourth sub-pixel of the third pixel column may be adjacent to any one of the second sub-pixel and the third sub-pixel of the second pixel column on one side of the second direction, and may be adjacent to any one of the first sub-pixel and the second sub-pixel of the first pixel column on the other side of the second direction. The first sub-pixel, the second sub-pixel, the third sub-pixel, and the fourth sub-pixel may have the same width in the first direction.

A plurality of pixels each comprising six sub-pixels adjacent to each other in the first direction or the second direction among the plurality of sub-pixels may be provided. Each of the plurality of pixels may include one first sub-pixel and one second sub-pixel adjacent to each other in the first pixel column; one third sub-pixel and one second sub-pixel adjacent to each other in the second pixel column; and two fourth sub-pixels in the third pixel column.

The arrangement pattern of the plurality of sub-pixels further may include an intersection column in which the fourth sub-pixels are arranged side by side in the second direction. The fourth sub-pixel corresponding to the first pixel column and the second pixel column in a first part of the intersection column is adjacent to at least one of the first sub-pixel of the first pixel column and the second sub-pixel of the second pixel column on one side of the first direction, and is adjacent to at least one of the second sub-pixel of the first pixel column and the third sub-pixel of the second pixel column on the other side of the first direction. The fourth sub-pixel corresponding to the third pixel column in the second part of the intersection column is adjacent to the fourth sub-pixel of the third pixel column in the first direction.

The fourth sub-pixel in the first part of the intersection column may be between the first sub-pixel of the first pixel column and the third sub-pixel of the second pixel column in a first diagonal direction intersecting the first direction and the second direction, and between the second sub-pixel of the first pixel column and the second sub-pixel of the second pixel column in a second diagonal direction perpendicular to the first diagonal direction.

The fourth sub-pixel of the third pixel column may be adjacent to the first sub-pixel and the second sub-pixel of the first pixel column on the other side of the second direction, and may be adjacent to the second sub-pixel and the third sub-pixel of the second pixel column on one side of the second direction. The fourth sub-pixel in the first part of the intersection column may be adjacent to sub-pixels in the first pixel column and the second pixel column in the first direction. The fourth sub-pixel in the second part of the intersection column may be adjacent to sub-pixels in the third pixel column in the first direction. Each of the first sub-pixel, the second sub-pixel, and the third sub-pixel may have a first width in the first direction. The fourth sub-pixel of the third pixel column may have a second width greater than twice the first width in the first direction. Each of the first sub-pixel, the second sub-pixel, and the third sub-pixel may have a third width in the second direction. The fourth sub-pixel in the first part of the intersection column may have a fourth width greater than twice the third width.

The fourth sub-pixel in the second part of the intersection column may have the first width in the first direction and the third width in the second direction.

The fourth sub-pixel of the third pixel column has a fifth width smaller than the third width in the second direction. The fourth sub-pixel in the first part of the intersection column has a sixth width smaller than the first width in the first direction. The fourth sub-pixel in the second part of the intersection column has the sixth width in the first direction and has the fifth width in the second direction.

A plurality of pixels each comprising seven sub-pixels adjacent to each other in the first direction and/or the second direction among the plurality of sub-pixels may be provided. Each of the plurality of pixels comprises one first sub-pixel and one second sub-pixel adjacent to each other in the first pixel column; one third sub-pixel and one second sub-pixel adjacent to each other in the second pixel column; one fourth sub-pixel in the third pixel column;

One fourth sub-pixel in the first part of the intersection column; and one fourth sub-pixel in the second part of the intersection column.

The fourth sub-pixel of the third pixel column may be adjacent to any one of the first sub-pixel of the first pixel column and the second sub-pixel of the second pixel column on one side of the second direction, and may be adjacent to any one of the second sub-pixel of the first pixel column and the third sub-pixel of the second pixel column on the other side of the second direction. The fourth sub-pixel in the first part of the intersection column may be adjacent to any one of the first sub-pixel of the first pixel column and the second sub-pixel of the second pixel column on one side of the first direction, and may be adjacent to any one of the second sub-pixel of the first pixel column and the third sub-pixel of the second pixel column on the other side of the first direction. The first sub-pixel, the second sub-pixel, the third sub-pixel, and the fourth sub-pixel may have the same width in each of the first direction and the second direction.

A plurality of pixels each comprising nine sub-pixels adjacent to each other in the first direction and/or the second direction among the plurality of sub-pixels may be provided. Each of the plurality of pixels may include one first sub-pixel and one second sub-pixel adjacent to each other in the first pixel column; one third sub-pixel and one second sub-pixel adjacent to each other in the second pixel column; two fourth sub-pixels in the third pixel column; two fourth sub-pixels in the first part of the intersection column; and one fourth sub-pixel in the second part of the intersection column.

A display device according to embodiments may include a plurality of sub-pixels arranged in a display area, and the plurality of sub-pixels may include a first sub-pixel corresponding to light of a first color, a second sub-pixel corresponding to light of a second color, a third sub-pixel corresponding to light of a third color, and a fourth sub-pixel corresponding to light of a fourth color. The first color, the second color, and the third color are different from each other, and the fourth color has a wavelength band wider than those of the first color, the second color, and the third color. A light emitting unit of each of the plurality of sub-pixels may include a light emitting element and a light adjustment layer covering the light emitting element.

Because the display device includes the fourth sub-pixel, it is unnecessary to drive all of the first sub-pixel, the second sub-pixel, and the third sub-pixel to display the fourth color. Therefore, power consumption for displaying the fourth color may be reduced.

Further, in accordance with one or more embodiments, the fourth color is displayed in the light emitting unit of the fourth sub-pixel, so that the light of the fourth color is not limited to a mixture of the first color, the second color, and the third color respectively corresponding to the first sub-pixel, the second sub-pixel, and the third sub-pixel. Accordingly, due to the light emitting unit of the fourth sub-pixel, the light of the fourth color may be similar to sunlight.

The effects of the present disclosure are not limited to the aforementioned effects, and various other effects are included in the present specification.

### BRIEF DESCRIPTION OF THE DRAWINGS

The above and other aspects and features of the present disclosure will become more apparent by describing in more detail embodiments thereof with reference to the attached drawings, in which:

FIG. 1 is a plan view illustrating a display device according to one or more embodiments;

FIG. 2 is a plan view illustrating a display area of FIG. 1;

FIG. 3 is a plan view showing a first example of part A of FIG. 2;

FIG. 4 is a circuit diagram showing any one sub-pixel illustrated in FIG. 3;

FIG. 5 is a cross-sectional view showing a display device taken along line B-B′ of FIG. 3 according to a first embodiment;

FIG. 6 is a cross-sectional view showing in more detail any one light emitting element shown in FIG. 5;

FIG. 7 is a cross-sectional view showing a display device taken along line B-B′ of FIG. 3 according to a second embodiment;

FIG. 8 is a cross-sectional view showing a display device taken along line B-B′ of FIG. 3 according to a third embodiment;

FIG. 9 is a cross-sectional view showing a display device taken along line B-B′ of FIG. 3 according to a fourth embodiment;

FIG. 10 is a cross-sectional view showing a display device taken along line B-B′ of FIG. 3 according to a fifth embodiment;

FIG. 11 is a cross-sectional view showing a display device taken along line B-B′ of FIG. 3 according to a sixth embodiment;

FIG. 12 is a cross-sectional view showing a display device taken along line B-B′ of FIG. 3 according to a seventh embodiment;

FIG. 13 is a cross-sectional view showing a display device taken along line B-B′ of FIG. 3 according to an eighth embodiment;

FIG. 14 is a cross-sectional view showing a display device taken along line B-B′ of FIG. 3 according to a ninth embodiment;

FIG. 15 is a plan view showing a second example of part A of FIG. 2;

FIG. 16 is a plan view showing a third example of part A of FIG. 2;

FIG. 17 is a plan view showing a fourth example of part A of FIG. 2;

FIG. 18 is a plan view showing a fifth example of part A of FIG. 2;

FIG. 19 is a plan view showing a sixth example of part A of FIG. 2;

FIG. 20 is a plan view showing a seventh example of part A of FIG. 2;

FIG. 21 is a plan view showing an eighth example of part A of FIG. 2;

FIG. 22 is a plan view showing a ninth example of part A of FIG. 2; and

FIG. 23 is a plan view showing a tenth example of part A of FIG. 2.

### DETAILED DESCRIPTION

The embodiments will now be described more fully hereinafter with reference to the accompanying drawings. The embodiments may, however, be provided in different forms and should not be construed as limiting. The same reference numbers indicate the same components throughout the disclosure. In the accompanying figures, the thickness of layers and regions may be exaggerated for clarity.

Some of the parts which are not associated with the description may not be provided in order to describe embodiments of the disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose (e.g., be positioned opposite) a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrases “at least one of,” “one of”, and “selected from”, when preceding a list of elements, modify the entire list of elements and do not modify the individual elements of the list. For example, “at least one selected from a, b and c”, “at least one of a, b or c”, and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning. For example consistent with their meaning in the context of the relevant art and will not be interpreted in an ideal or excessively formal sense unless clearly defined in the specification.

Hereinafter, embodiments will be described with reference to the accompanying drawings.

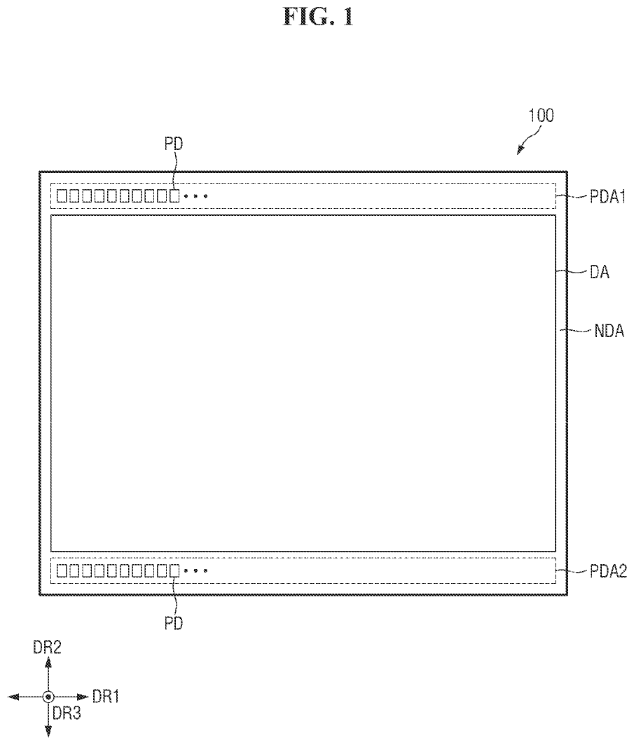

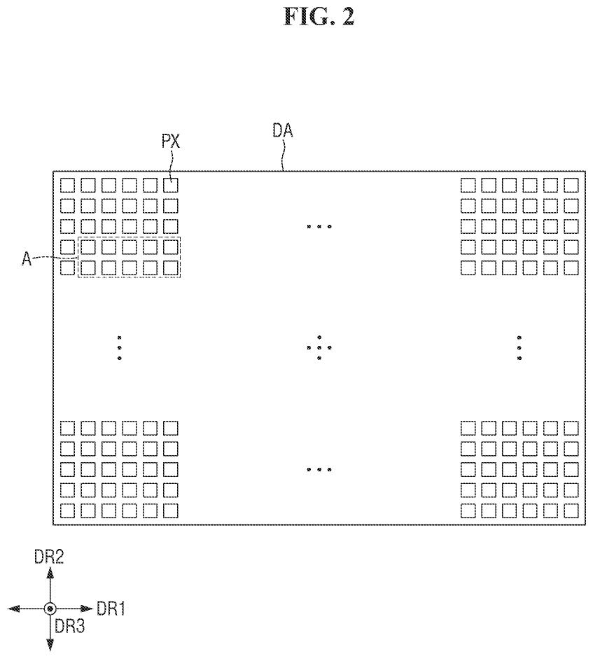

FIG. 1 is a plan view illustrating a display device according to one or more embodiments. FIG. 2 is a plan view illustrating a display area of FIG. 1.

Referring to FIG. 1, a display device 100 is a device for displaying a moving image and/or a still image. The display device 100 may be used as a display screen of various suitable devices, such as a television, a laptop computer, a monitor, a billboard and/or an Internet-of-Things (IOT) device, as well as portable electronic devices such as a mobile phone, a smartphone, a tablet personal computer (PC), a smart watch, a watch phone, a mobile communication terminal, an electronic notebook, an electronic book, a portable multimedia player (PMP), a navigation device and/or an ultra-mobile PC (UMPC).

The display device 100 may be formed in a flat panel shape, and at least one surface of the display device 100 may be a display surface on which an image is displayed.

The display surface of the display device 100 includes a display area DA emitting (e.g., configured to emit) light for displaying an image, and a non-display area NDA surrounding (e.g., around) the display area.

The display area DA may have a planar surface of a polygonal shape such as a quadrilateral shape or a circular shape. For example, the display area DA may have a planar surface of a rectangular shape having a long side in a first direction DR1 and a short side in the second direction DR2 crossing the first direction DR1.

In the display area DA of a rectangular shape, a contact point between the long side in the first direction DR1 and the short side in the second direction DR2 may form a right-angled corner. In some embodiments, the contact point between the long side in the first direction DR1 and the short side in the second direction DR2 may also form a curved corner having a set or predetermined curvature.

The display area DA may correspond to most of the center of the light emitting surface of the display device 100, and may be surrounded by the non-display area NDA.

The non-display area NDA may correspond to the edge of the light emitting surface of the display device 100. The non-display area NDA may include a first pad area PDA1 and a second pad area PDA2 adjacent to both sides of the edges of the display area DA in the second direction DR2.

A plurality of signal pads PD to which an external circuit board for supplying a signal or a voltage for driving the display panel is connected may be provided in each of the first pad area PDA1 and the second pad area PDA2.

However, the illustration of FIG. 1 is only an example, and the non-display area NDA may include only one of the first pad area PDA1 and the second pad area PDA2.

Referring to FIG. 2, a plurality of pixels PX arranged in the first direction DR1 and the second direction DR2 may be provided in the display area DA.

As will be described in more detail herein below, each of the plurality of pixels PX may include four or more sub-pixels that are adjacent to each other in the first direction DR1 or the second direction DR2 and that emit lights of different colors.

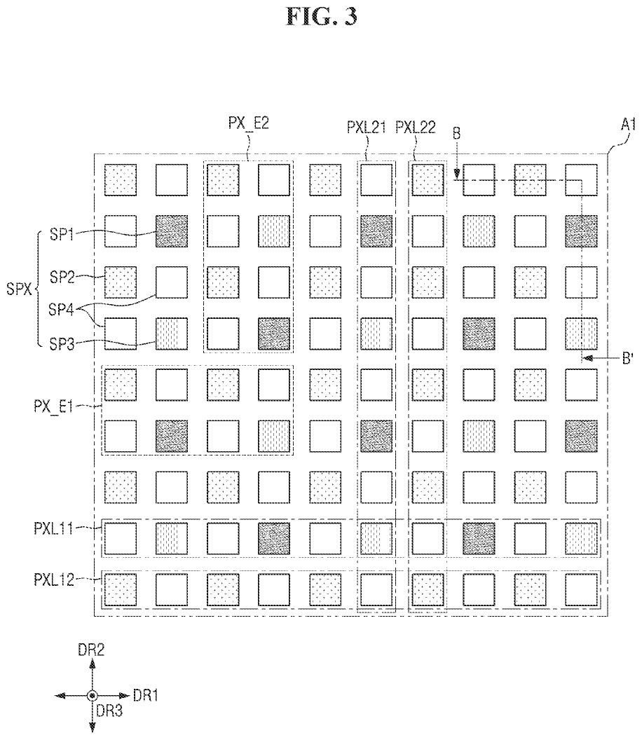

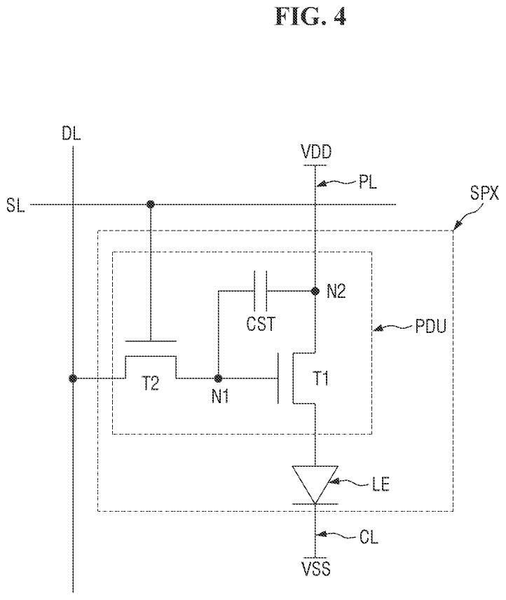

FIG. 3 is a plan view showing an example of part A of FIG. 2. FIG. 4 is a circuit diagram showing any one sub-pixel illustrated in FIG. 3.

Referring to FIG. 3, a plurality of sub-pixels SPX may be arranged in the first direction DR1 and the second direction DR2 in the display area DA of the display device according to a first example A1.

The plurality of sub-pixels SPX include a first sub-pixel SP1 corresponding to light of a first color, a second sub-pixel SP2 corresponding to light of a second color different from the first color, a third sub-pixel SP3 corresponding to light of a third color different from the first color and the second color, and a fourth sub-pixel SP4 corresponding to light of a fourth color having a wavelength band wider than those of the first color, the second color, and the third color.

For example, the first color may be red having a wavelength band of approximately 620 nm to 750 nm, and the second color may be green having a wavelength band lower than that of the first color, e.g., a wavelength band of approximately 490 nm to 570 nm. The third color may be blue having a wavelength band lower than that of the second color, e.g., a wavelength band of approximately 420 nm to 450 nm.

In one or more embodiments, the fourth color may be white corresponding to a mixture of two or more different wavelength bands among the wavelength bands of light.

For example, the minimum value of the wavelength band of the fourth color may be close to the minimum value of the wavelength band of the third color, and the maximum value of the wavelength band of the fourth color may be close to the maximum value of the wavelength band of the first color. For example, the wavelength band of the fourth color may include two or more main peak wavelengths selected as different parts of a wavelength band of 420 nm to 750 nm.

However, the description of the wavelength bands of the first color, the second color, the third color, and the fourth color is only an example, and the embodiments of this specification are not limited thereto.

The arrangement pattern of the plurality of sub-pixels SPX according to the first example A1 may include a first pixel column PXL11 of the first direction DR1 and a second pixel column PXL12 of the first direction DR1 that alternate with each other in the second direction DR2.

In the first pixel column PXL11 of the first direction DR1, the first sub-pixel SP1, the fourth sub-pixel SP4, the third sub-pixel SP3, and the fourth sub-pixel SP4 are repeatedly arranged side by side in the first direction DR1.

In the second pixel column PXL12 of the first direction DR1, the second sub-pixel SP2 and the fourth sub-pixel SP4 are repeatedly arranged side by side in the first direction DR1.

Here, each of the first sub-pixels SP1 and the third sub-pixels SP3 of the first pixel column PXL11 (of the first direction DR1) is adjacent to the fourth sub-pixel SP4 of the second pixel column PXL12 (of the first direction DR1) in the second direction DR2.

The second sub-pixel SP2 of the second pixel column PXL12 (of the first direction DR1) is adjacent to the fourth sub-pixel SP4 of the first pixel column PXL11 (of the first direction DR1) in the second direction DR2.

For example, the sides of each of the first sub-pixel SP1, the second sub-pixel SP2, and the third sub-pixel SP3 in the first direction DR1 and the second direction DR2 are adjacent to the fourth sub-pixel SP4.

Further, in accordance with the first example A1, there may be provided a plurality of pixels PX_E1, each including eight sub-pixels SPX adjacent to each other in the first direction DR1 and the second direction DR2 among the plurality of sub-pixels SPX.

For example, each of the plurality of pixels PX_E1 may include one first sub-pixel SP1, one third sub-pixel SP3, and two fourth sub-pixels SP4 adjacent in the first direction DR1 in the first pixel columns PXL11 of the first direction DR1, and two second sub-pixels SP2 and two fourth sub-pixels SP4 adjacent in the first direction DR1 in the second pixel column PXL12 of the first direction DR1.

In the above, the case in which the arrangement pattern of the plurality of sub-pixels SPX according to the first example A1 includes the first pixel column PXL11 of the first direction DR1 and the second pixel column PXL12 of the first direction DR1 has been described. However, in accordance with the first example A1, the sides of each of the first sub-pixel SP1, the second sub-pixel SP2, and the third sub-pixel SP3 in the first direction DR1 and the second direction DR2 are adjacent to the fourth sub-pixel SP4, such that the arrangement pattern of the plurality of sub-pixels SPX includes a first pixel column PXL21 and a second pixel column PXL22 in the second direction DR2 instead of the first direction DR1, which may also be included within the scope of the present disclosure.

For example, the arrangement pattern of the plurality of sub-pixels SPX according to the first example A1 may include the first pixel column PXL21 of the second direction DR2 and the second pixel column PXL22 of the second direction DR2 that alternate each other in the first direction DR1.

In the first pixel column PXL21 of the second direction DR2, the first sub-pixel SP1, the fourth sub-pixel SP4, the third sub-pixel SP3, and the fourth sub-pixel SP4 are repeatedly arranged side by side in the second direction DR2.

In the second pixel column PXL22 of the second direction DR2, the second sub-pixel SP2 and the fourth sub-pixel SP4 are repeatedly arranged side by side in the second direction DR2.

Each of the first sub-pixel SP1 and the third sub-pixel SP3 of the first pixel column PXL21 of the second direction DR2 is adjacent to the fourth sub-pixel SP4 of the second pixel column PXL22 of the second direction DR2 in the first direction DR1.

The second sub-pixel SP2 of the second pixel column PXL22 of the second direction DR2 is adjacent to the fourth sub-pixel SP4 of the first pixel column PXL21 of the second direction DR2 in the first direction DR1.

Here, each of a plurality of pixels PX_E2 may include one first sub-pixel SP1, one third sub-pixel SP3, and two fourth sub-pixels SP4 adjacent in the second direction DR2 in the first pixel columns PXL21 of the second direction DR2, and two second sub-pixels SP2 and two fourth sub-pixels SP4 adjacent in the second direction DR2 in the second pixel columns PXL22 of the second direction DR2.

In accordance with the first example A1, each of the plurality of pixels PX_E1 (PX_E2) may display a color using the light of the first color emitted from one first sub-pixel SP1, the light of the second color emitted from two second sub-pixels SP2, and the light of the third color emitted from one third sub-pixel SP3.

In some embodiments, each of the plurality of pixels PX_E1 (PX_E2) may display the light of the fourth color using four fourth sub-pixels SP4 adjacent to one first sub-pixel SP1, two second sub-pixels SP2, and one third sub-pixel SP3.

For example, each of the plurality of pixels PX_E1 (PX_E2) display the light of the fourth color using at least one of the four fourth sub-pixels SP4 instead of displaying the light of the fourth color by mixing the light of the first color, the light of the second color, and the light of the third color. For example, in each of the plurality of pixels PX_E1 (PX_E2), it is unnecessary to drive all of the first sub-pixel SP1, the second sub-pixel SP2, and the third sub-pixel SP3 to display the light of the fourth color.

Further, in each of the plurality of pixels PX_E1 (PX_E2) and the four fourth sub-pixels SP4 may be selectively and individually driven to allow each pixel display the light of the fourth color with more variously divided grayscales.

Therefore, the display device 100 according to the embodiments may reduce power consumption for displaying the light of the fourth color.

In one or more embodiments, the display device 100 may include a pixel driving unit PDU (see FIG. 4) of each of the plurality of sub-pixels SPX to individually drive the plurality of sub-pixels SPX.

Referring to FIG. 4, each of the plurality of sub-pixels SPX may include a light emitting element LE and the pixel driving unit PDU for supplying a driving current thereto.

The pixel driving unit PDU may be connected to a scan line SL for supplying a scan signal for selecting whether or not to write data, a data line DL for supplying a data signal, and a power line PL for suppling a first driving power VDD for driving the light emitting element LE, and may include one or more thin film transistors T1 and T2.

For example, the pixel driving unit PDU may include a first thin film transistor T1 connected to the light emitting element LE, a second thin film transistor T2 connected to the first thin film transistor T1, and a storage capacitor CST.

The first thin film transistor T1 is connected in series with the light emitting element LE between the power line PL for supplying the first driving power VDD and a common line CL for supplying a second driving power VSS having a voltage level lower than that of the first driving power VDD.

For example, the first electrode of the first thin film transistor T1 may be connected to the power line PL, and the second electrode of the first thin film transistor T1 may be connected to the anode electrode of the light emitting element LE.

Further, the cathode electrode of the light emitting element LE may be connected to the common line CL.

The second thin film transistor T2 is connected between the gate electrode of the first thin film transistor T1 and the data line DL for supplying the data signal corresponding to each sub-pixel SPX. Further, the gate electrode of the second thin film transistor T2 is connected to the scan line SL for supplying the scan signal for selecting whether or not to write the data signal.

The storage capacitor CST is connected between a first node N1 and a second node N₂. The first node N1 is the contact point between the gate electrode of the first thin film transistor T1 and the second thin film transistor T2, and the second node N₂ is the contact point between the first thin film transistor T1 and the power line PL. For example, the storage capacitor CST is connected between the gate electrode and the first electrode of the first thin film transistor T1.

When the second thin film transistor T2 is turned on based on the scan signal of the scan line SL, the data signal of the data line DL is transmitted to the gate electrode of the first thin film transistor T1 and the storage capacitor CST through the turned-on second thin film transistor T2. Accordingly, the first thin film transistor T1 is turned on based on the data signal, and a driving current corresponding to the data signal is supplied to the light emitting element LE through the turned-on first thin film transistor T1. Further, the first thin film transistor T1 may maintain the turn-on state based on the voltage charged in the storage capacitor CST.

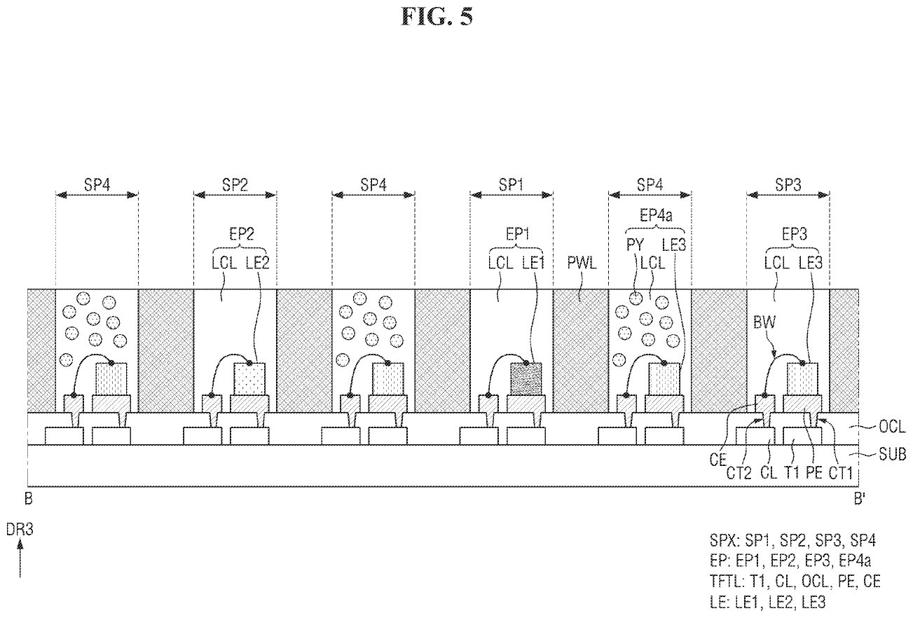

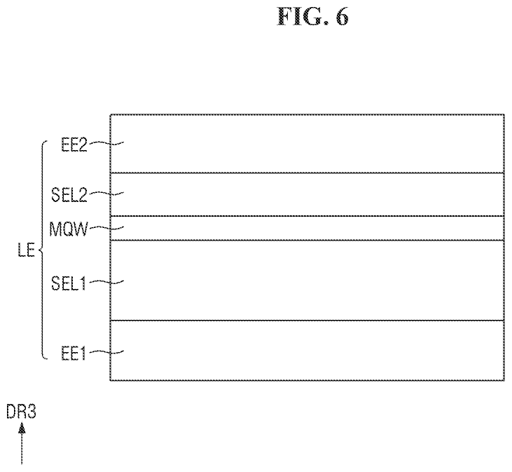

FIG. 5 is a cross-sectional view showing a display device taken along line B-B′ of FIG. 3 according to one or more embodiments. FIG. 6 is a cross-sectional view showing in more detail any one light emitting element shown in FIG. 5.

Referring to FIG. 5, the display device 100 according to the one or more embodiments includes a substrate SUB including the display area DA (see FIGS. 1 and 2) where the plurality of sub-pixels SPX are arranged, a plurality of light emitting units EP provided on the substrate SUB and respectively corresponding to the plurality of sub-pixels SPX, and a partition wall PWL provided on the substrate SUB and corresponding to the boundary between the plurality of sub-pixels SPX.

The light emitting unit EP of each of the plurality of sub-pixels SPX includes the light emitting element LE and a light adjustment layer LCL covering the light emitting element LE, and is adjacent to (e.g., is surrounded by) the partition wall PWL.

The plurality of sub-pixels SPX according to the first embodiment includes the first sub-pixel SP1 corresponding to the light of the first color, the second sub-pixel SP2 corresponding to the light of the second color different from the first color, the third sub-pixel SP3 corresponding to the light of the third color different from the first color and the second color, and the fourth sub-pixel SP4 corresponding to the light of the fourth color having a wavelength band wider than those of the first color, the second color, and the third color.

Accordingly, the plurality of light emitting units EP may include a first light emitting unit EP1 corresponding to the first sub-pixel SP1 and emitting (e.g., configured to emit) the light of the first color, a second light emitting unit EP2 corresponding to the second sub-pixel SP2 and emitting (e.g., configured to emit) the light of the second color, a third light emitting unit EP3 corresponding to the third sub-pixel SP3 and emitting (e.g., configured to emit) the light of the third color, and a fourth light emitting unit EP4a corresponding to the fourth sub-pixel SP4 and emitting (e.g., configured to emit) the light of the fourth color.

Here, the second color may have a wavelength band lower than that of the first color, and the third color may have a wavelength band lower than that of the second color. For example, the first color, the second color, and the third color may be red, green, and blue, respectively. Further, the fourth color may be white having a wavelength band wider than those of red, green, and blue.

The substrate SUB may be provided in the form of a rigid flat plate. In some embodiments, the substrate SUB may be provided in the form of a flexible flat plate which can be (e.g., easily) bent, folded, and/or rolled.

The display device 100 according to the first embodiment may further include a transistor array layer TFTL provided on the substrate SUB and including the pixel driving unit PDU (see FIG. 4) of each of the plurality of sub-pixels SPX.

The substrate SUB may be formed of an insulating material such as glass, quartz, and/or a polymer resin. Examples of the polymer resin may include polyethersulfone (PES), polyacrylate (PA), polyarylate (PAR), polyetherimide (PEI), polyethylene naphthalate (PEN), polyethylene terephthalate (PET), polyphenylene sulfide (PPS), polyallylate, polyimide (PI), polycarbonate (PC), cellulose triacetate (TAC), cellulose acetate propionate (CAP), or a combination thereof.

In one or more embodiments, the substrate SUB may be made of a metal material.

The substrate SUB supports the transistor array layer TFTL, the plurality of light emitting units EP, the partition wall PWL, and/or the like provided thereon.

Here, the pixel driving unit PDU may include the first thin film transistor T1 connected to the light emitting element LE, and the second thin film transistor T2 (see FIG. 4) connected between the first thin film transistor T1 and the data line DL (see FIG. 4).

In one or more embodiments, the first thin film transistor T1 may include an active layer made of a semiconductor material and a gate electrode overlapping the channel region of the active layer.

The active layer further includes a source region and a drain region in contact with both sides of the channel region. One of the source region or the drain region of the active layer may be connected to the power line PL (see FIG. 4), and the other may be connected to a pixel electrode PE through a first contact hole CT1 or the like.

In one or more embodiments, the transistor array layer TFTL may further include the scan line SL (see FIG. 4), the data line DL (see FIG. 4), and the power line PL (see FIG. 4) that are connected to the pixel driving unit PDU, and the common line CL connected to the light emitting element LE.

The common line CL may be provided on a layer different from the first thin film transistor T1 by a set or predetermined insulating layer or spaced apart from the first thin film transistor T1 to be insulated from the first thin film transistor T1.

The transistor array layer TFTL may further include an overcoat layer OCL covering at least one thin film transistor T1 constituting the pixel driving unit PDU, and various lines SL, DL, PL, and CL such as the common line CL and/or the like.

The overcoat layer OCL may be made of any organic insulating material among acrylic resin, epoxy resin, phenolic resin, polyamide resin, and/or polyimide resin. In some embodiments, the overcoat layer OCL may further contain an inorganic insulating material and may be formed as multiple layers.

The transistor array layer TFTL may further include the pixel electrode PE and a common electrode CE provided on the overcoat layer OCL and spaced apart from each other while corresponding to each of the plurality of sub-pixels SPX.

The pixel electrode PE and the common electrode CE may be formed as a single layer or multiple layers made of at least one of molybdenum (Mo), aluminum (Al), chromium (Cr), gold (Au), titanium (Ti), nickel (Ni), neodymium (Nd), and copper (Cu) or an alloy thereof.

The pixel electrode PE may be connected to the first thin film transistor T1 through the first contact hole CT1 penetrating the overcoat layer OCL.

The common electrode CE may be connected to the common line CL through a second contact hole CT2 penetrating the overcoat layer OCL.

A part of the common electrode CE may overlap the partition wall PWL.

The light emitting unit EP of each of the plurality of sub-pixels SPX may be provided on the transistor array layer TFTL.

The light emitting element LE of each of the plurality of light emitting units EP may be provided on the pixel electrode PE of the transistor array layer TFTL.

For example, as shown in FIG. 6, the light emitting element LE may be a vertical type (or kind) light emitting element. For example, the light emitting element LE may include a first light emitting electrode EE1 and a second light emitting electrode EE2 facing each other.

The light emitting element LE may further include a first semiconductor layer SEL1, an active layer MQW, and a second semiconductor layer SEL2 provided between the first light emitting electrode EE1 and the second light emitting electrode EE2.

The first semiconductor layer SEL1 may be formed of a p-GaN semiconductor provided on the first light emitting electrode EE1 and doped with a p-type dopant. For example, the first semiconductor layer SEL1 may contain the p-type dopant such as Mg, Zn, Ca, Sr, Ba, and/or the like.

The light emitting element LE may further include an electron blocking layer provided between the first semiconductor layer SEL1 and the active layer MQW. The electron blocking layer may be made of p-AlGaN doped with a p-type dopant. The movement of electrons from the active layer MQW to the first semiconductor layer SEL1 may be prevented or reduced by the electron blocking layer.

In the active layer MQW, electron-hole pairs are generated by recombining holes and electrons respectively supplied from the first semiconductor layer SEL1 and the second semiconductor layer SEL2 by the driving current, and energy is released in the form of photons.

The active layer MQW may have a single or multiple quantum well structure.

For example, the active layer MQW may have a multiple quantum well structure in which a well layer and a barrier layer are alternately stacked. Here, the well layer may be made of InGaN. In some embodiments, the barrier layer may be made of GaN and/or AlGaN. The well layer may have a thickness of approximately 1 nm to 4 nm, and the barrier layer may have a thickness of approximately 3 nm to 10 nm. However, this is only an example, and the material and structure of the active layer MQW of the light emitting element LE may be variously suitably changed.

For example, for another example, the active layer MQW may have a structure in which a semiconductor material having a large energy band gap and a semiconductor material having a small energy band gap are alternately stacked.

For yet another example, the active layer MQW may include group III to V semiconductor materials corresponding to the wavelength band of the target color of the light emitting element LE.

The light emitting element LE may further include a superlattice layer provided between the active layer MQW and the second semiconductor layer SEL2 to reduce a stress difference between the active layer MQW and the second semiconductor layer SEL2. The superlattice layer may be made of InGaN and/or GaN.

The second semiconductor layer SEL2 may be formed of an n-GaN semiconductor provided under the second light emitting electrode EE2 and doped with an n-type dopant. For example, the second semiconductor layer SEL2 may contain the n-type dopant such as Si, Ge, Se, Sn, and/or the like.

As shown in FIG. 5, the first light emitting electrode EE1 (see FIG. 6) of the vertical type (or kind) light emitting element LE may be fixed on the pixel electrode PE by a conductive adhesive material to be electrically connected (e.g., electrically coupled) to the pixel electrode PE. Further, the second light emitting electrode EE2 (see FIG. 6) of the vertical type (or kind) light emitting element LE may be connected to the common electrode CE through a separate bonding wire BW.

However, this is only an example, and the light emitting element LE of the first embodiment is not limited to the vertical type (or kind) light emitting element shown in FIG. 6.

In one or more other embodiments, the light emitting element LE may be a lateral type (or kind) light emitting element including a first light emitting electrode and a second light emitting electrode spaced apart from each other on a surface facing the pixel electrode PE. In the lateral type (or kind) light emitting element, a first semiconductor layer of a first conductivity type (or kind), an active layer, and a second semiconductor layer of a second conductivity type (or kind) may be sequentially stacked, the first light emitting electrode may be provided on a part of the second semiconductor layer and on the first semiconductor layer exposed by removing a part of the active layer connected thereto, and the second light emitting electrode may be provided on another part of the second semiconductor layer. In this lateral type (or kind) light emitting element, the first light emitting electrode and the second light emitting electrode may be respectively connected to the pixel electrode PE and the common electrode CE through respective bonding wires.

In some embodiments, the light emitting element LE may be a flip type (or kind) light emitting element including a first light emitting electrode and a second light emitting electrode spaced apart from each other on a surface facing the pixel electrode PE. In this flip type (or kind) light emitting element, the first light emitting electrode and the second light emitting electrode respectively facing the pixel electrode PE and the common electrode CE are respectively provided on the pixel electrode PE and the common electrode CE to be respectively connected to the pixel electrode PE and the common electrode CE.

As illustrated in FIG. 5, the display device 100 according to the first embodiment includes the plurality of light emitting units EP provided on the substrate SUB and the partition wall PWL provided to surround the peripheries of the plurality of light emitting units EP.

The partition wall PWL may contain a material that absorbs light and/or a material that reflects light.

The plurality of light emitting units EP may correspond to the plurality of sub-pixels SPX, respectively, by the partition wall PWL, and may emit light.

The plurality of light emitting units EP respectively corresponding to the plurality of sub-pixels SPX include the first light emitting unit EP1 corresponding to the first sub-pixel SP1 and emitting the light of the first color, the second light emitting unit EP2 corresponding to the second sub-pixel SP2 and emitting the light of the second color, the third light emitting unit EP3 corresponding to the third sub-pixel SP3 and emitting the light of the third color, and the fourth light emitting unit EP4a corresponding to the fourth sub-pixel SP4 and emitting the light of the fourth color.

Each of the plurality of light emitting units EP includes the light emitting element LE provided on the substrate SUB and emitting (e.g., configured to emit) light, and the light adjustment layer LCL that covers the light emitting element LE and controls the light of the light emitting element LE.

Further, each of the plurality of light emitting units EP is adjacent to (e.g., is surrounded by) the partition wall PWL. For example, the light adjustment layer LCL of each of the plurality of light emitting units EP is adjacent to (e.g., is surrounded by) the partition wall PWL.

The light adjustment layer LCL may guide the light of the light emitting element LE and change the color of the light to correspond to the color of the light emitted by each sub-pixel SPX. The light adjustment layer LCL may include a base resin made of an organic material that is cured by ultraviolet rays or heat and has a light-transmitting property. For example, the base resin may include at least one of an epoxy-based resin, an acrylic-based resin, a cardo-based resin, and an imide-based resin.

The light adjustment layer LCL may further include a scatterer that is dispersed in the base resin and scatters the light of the light emitting element LE. The scatterer may be made of a material having a reflectivity of 95% or higher, and may have a substantially spherical shape. The size of the scatterer may be within a range of 10 nm to 500 nm. For example, the scatterer may be made of at least one metal oxide selected from among titanium oxide (TiO₂), silicon oxide (SiO₂), aluminum oxide (Al₂O₃), and zirconium oxide (ZrO₂). When the light adjustment layer LCL includes the scatterer, the light emission efficiency of each light emitting unit EP may be increased.

In some of the plurality of light emitting units EP, the light of the light emitting element LE may be different from the color of the sub-pixel SPX. In this case, a phosphor that is dispersed in the light adjustment layer LCL and shifts the wavelength band of the light of the light emitting element LE to a higher wavelength band may be further included. This will be described in more detail herein below.

In accordance with the first embodiment, the first light emitting unit EP1 includes the first light emitting element LE1 emitting the light of the first color corresponding to the first sub-pixel SP1. The first light emitting unit EP1 emits the light of the first color from the first light emitting element LE1 through the light adjustment layer LCL. The first color may be red corresponding to a wavelength band of approximately 620 nm to 750 nm.

The second light emitting unit EP2 includes the second light emitting element LE2 emitting the light of the second color corresponding to the second sub-pixel SP2. The second light emitting unit EP2 emits the light of the second color from the second light emitting element LE2 through the light adjustment layer LCL. The second color may be green corresponding to a wavelength band of approximately 490 nm to 570 nm.

The third light emitting unit EP3 includes the third light emitting element LE3 emitting the light of the third color corresponding to the third sub-pixel SP3. The third light emitting unit EP3 emits the light of the third color from the third light emitting element LE3 through the light adjustment layer LCL. The third color may be blue corresponding to a wavelength band of approximately 400 nm to 420 nm.

Here, the first light emitting element LE1, the second light emitting element LE2, and the third light emitting element LE3 may include the active layers MQW (see FIG. 6) made of different materials or having different compositions and/or different thicknesses to emit lights of different wavelength bands.

The fourth sub-pixel SP4 may correspond to the fourth color, e.g., white, having a wavelength band wider than those of the first color, the second color, and the third color. However, the light emitting element emitting white light is relatively expensive, and it is inconvenient to provide the light emitting element emitting white light separately from the first, second, and third light emitting elements LE1, LE2, and LE3. Accordingly, in order to facilitate the process and reduce manufacturing cost, the fourth light emitting unit EP4a according to the first embodiment may include the third light emitting element LE3 emitting the light of the third color, similarly to the third light emitting unit EP3.

Further, the fourth light emitting unit EP4a may further include a phosphor PY of a fifth color dispersed in the light adjustment layer LCL, in addition to the third light emitting element LE3 emitting the light of the third color, in order to emit the light of the fourth color having a wavelength band wider than that of the third color.

The fifth color may correspond to the wavelength band between the wavelength band of the first color and the wavelength band of the second color. As described above, the first color may be red having a wavelength band of approximately 620 nm to 750 nm, and the second color may be green having a wavelength band lower than that of the first color, e.g., a wavelength band of approximately 490 nm to 570 nm. In this case, the fifth color may be yellow corresponding to the wavelength band of approximately 570 nm to 620 nm between the wavelength band of the first color and the wavelength band of the second color. For example, the main peak wavelength of the fifth color may be approximately 570 nm to 590 nm.

The phosphor PY of the fifth color converts a part of the light of the third color (e.g., blue light) emitted from the third light emitting element LE3 to the light of the fifth color (e.g., yellow) having a wavelength band higher than that of the third color.

For example, the phosphor PY of the fifth color may be selected as (Y,Gd)₃(Al,Ga)₅O₁₂:Ce³⁺ and/or (Lu,Y)₃(Al,Ga)₅O₁₂:Ce³⁺.

Accordingly, the fourth light emitting unit EP4a according to the embodiments may emit the light of the fourth color (e.g., white) generated by mixing the light of the third color (e.g., blue) from the third light emitting element LE3 and the light of the fifth color (e.g., yellow) from the phosphor PY.

For example, the light of the fourth color emitted from the fourth light emitting unit EP4a of the first embodiment may have two main peak wavelengths including a wavelength band of approximately 400 nm to 420 nm corresponding to the third color and a wavelength band of approximately 560 nm to 600 nm corresponding to the fifth color.

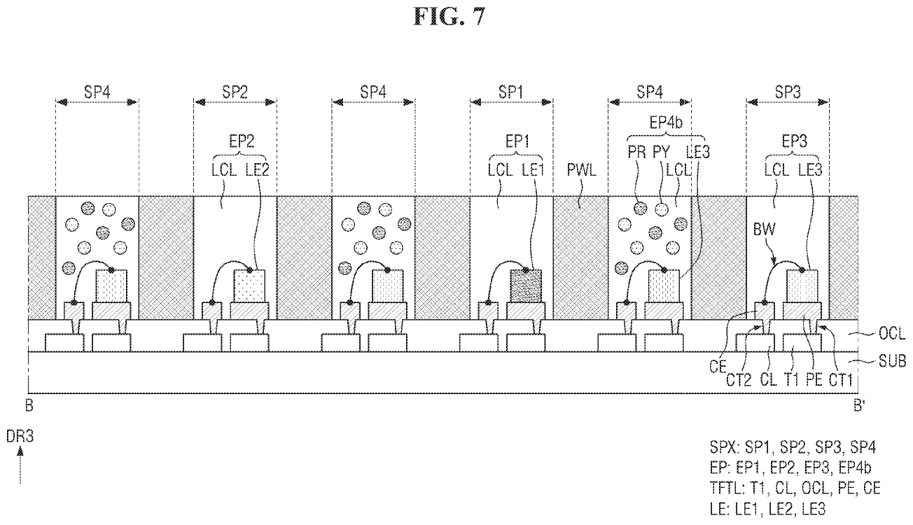

FIG. 7 is a cross-sectional view showing a display device taken along line B-B′ of FIG. 3 according to a second embodiment.

Referring to FIG. 7, the display device according to the second embodiment is the same as the display device according to the first embodiment shown in FIG. 5 except that the fourth light emitting unit EP4b further includes a phosphor PR of the first color dispersed in the light adjustment layer LCL together with the phosphor PY of the fifth color, and redundant descriptions will not be provided in the following description.

The phosphor PR of the first color converts a part of the light (e.g., blue light) of the third color emitted from the third light emitting element LE3 to the light of the first color (e.g., red) having a wavelength band higher than that of the third color.

For example, the phosphor PR of the first color may be selected as (Sr, Ca)AlSiN₃:Eu²⁺.

Accordingly, the fourth light emitting unit EP4b according to the second embodiment may emit the light of the fourth color (e.g., white) generated by mixing the light of the third color (e.g., blue) from the third light emitting element LE3, the light of the fifth color (e.g., yellow) from the phosphor PY, and the light of the first color (e.g., red) from the phosphor PR of the first color.

For example, the light of the fourth color emitted from the fourth light emitting unit EP4b of the second embodiment may have three main peak wavelengths including a wavelength band of approximately 400 nm to 420 nm corresponding to the third color, a wavelength band of approximately 560 nm to 600 nm corresponding to the fifth color, and a wavelength band of approximately 620 nm to 750 nm corresponding to the first color.

Therefore, the light of the fourth color from the fourth light emitting unit EP4b of the second embodiment may exhibit a higher Color Rendering Index (CRI) compared to the light of the fourth color from the fourth light emitting unit EP4a of the first embodiment. Here, CRI is a parameter indicating a degree of similarity between white light and sunlight between about 12 o'clock (e.g., noon) and 14 o'clock (e.g., 2:00 P.M.).

For example, the light of the fourth color from the fourth light emitting unit EP4a of the first embodiment, which is generated by mixing the third color and the fifth color and exhibits a CRI of about 65 to 70, may be recognized as white indoors.

By way of comparison, the light of the fourth color from the fourth light emitting unit EP4a of the second embodiment, which is generated by mixing the first color, the third color, and the fifth color and exhibits a CRI of about 70 to 80, may be recognized as white outdoors as well as indoors.

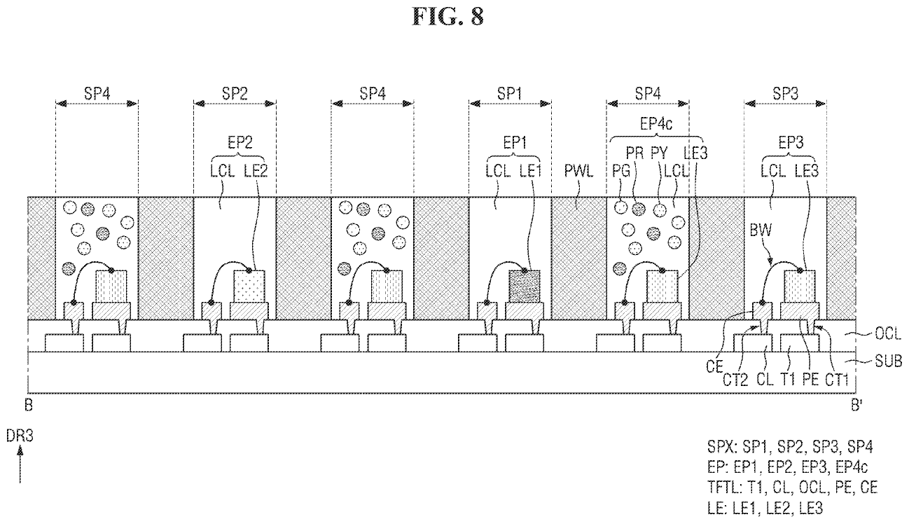

FIG. 8 is a cross-sectional view showing a display device taken along line B-B′ of FIG. 3 according to a third embodiment.

Referring to FIG. 8, the display device according to the third embodiment is the same as the display device according to the second embodiment shown in FIG. 7 except that a fourth light emitting unit EP4c further includes a phosphor PG of the second color dispersed in the light adjustment layer LCL together with the phosphor PY of the fifth color and the phosphor PR of the first color, and redundant descriptions will not be provided in the following description.

The phosphor PG of the second color converts a part of the light of the third color (e.g., blue light) emitted from the third light emitting element LE3 to the light of the second color (e.g., green) having a wavelength band higher than that of the third color.

The phosphor PY of the fifth color included in the fourth light emitting unit EP4c of the third embodiment may be selected as at least one of (Y,Gd)₃(Al,Ga)₅O₁₂:Ce³⁺, (Lu,Y)₃(Al,Ga)₅O₁₂:Ce³⁺, (Sr, Ba, Mg)SiO₄:Eu²⁺, and (Sr, Ba, Mg)SiO₂N₂:Eu²⁺.

The phosphor PR of the first color included in the fourth light emitting unit EP4c of the third embodiment may be selected as at least one of (Sr, Ca)AlSiN₃:Eu²⁺, K₂SiF₆:Mn⁴⁺, Na₂SiF₆:Mn⁴⁺, KNaSiF₆:Mn⁴⁺, K₂GeF₆:Mn⁴⁺, K₂TiF₆:Mn⁴⁺, Mg₄GeO₃F:Mn⁴⁺, 3.5MgO·0.5MgF₂·GeO₂:Mn⁴⁺, Sr(Li₂Al₂O₂N₂):Eu²⁺, (Sr, Ba)₂Si₅N₈:Eu²⁺, BaMgAl₁₀O₁₇:Mn⁴⁺, Mg²⁺, CaS:Eu²⁺, InP (QDs), and CsPbI₃ (Perovskite QDs).

The phosphor PG of the second color included in the fourth light emitting unit EP4c of the third embodiment may be selected as at least one of (Sr, Ba, Mg)₂SiO₄:Eu²⁺, Lu₃(Al,Ga)₅O₁₂:Ce³⁺, Ba₃Si₆O₁₂N₂:Eu²⁺, SrGa₂S₄:Eu²⁺, Gamma AlON:Eu²⁺, InP (QDs), and CsPbBr₃ (QDs)(Perovskite QDs).

Accordingly, the fourth light emitting unit EP4c according to the third embodiment may emit the light of the fourth color (e.g., white) generated by mixing the light of the third color (e.g., blue) from the third light emitting element LE3, the light of the second color (e.g., green) from the phosphor PG of the second color, the light of the fifth color (e.g., yellow) from the phosphor PY of the fifth color, and the light of the first color (e.g., red) from the phosphor PR of the first color.

For example, the light of the fourth color emitted from the fourth light emitting unit EP4c of the third embodiment may have four main peak wavelengths including a wavelength band of approximately 400 nm to 420 nm corresponding to the third color, a wavelength band of approximately 490 nm to 570 nm corresponding to the second color, a wavelength band of approximately 560 nm to 600 nm corresponding to the fifth color, and a wavelength band of approximately 620 nm to 750 nm corresponding to the first color.

Therefore, the light of the fourth color from the fourth light emitting unit EP4c of the third embodiment may exhibit a higher CRI compared to the light of the fourth color from the fourth light emitting unit EP4b of the second embodiment.

For example, the light of the fourth color from the fourth light emitting unit EP4c of the third embodiment, which is generated by mixing the first color, the second color, the third color, and the fifth color and exhibits a CRI of approximately 80 to 90, may be used as a lighting.

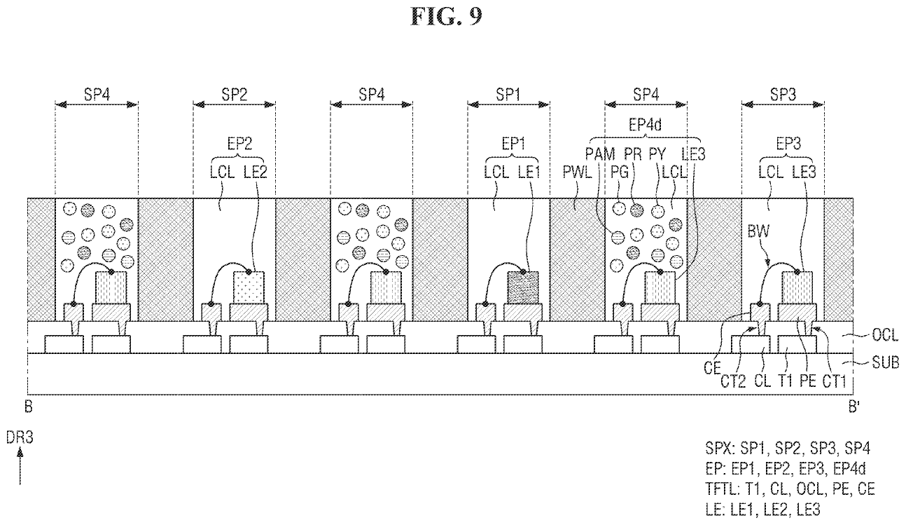

FIG. 9 is a cross-sectional view showing a display device taken along line B-B′ of FIG. 3 according to a fourth embodiment.

Referring to FIG. 9, the display device according to the fourth embodiment is the same as the display device according to the third embodiment shown in FIG. 8 except that a fourth light emitting unit EP4d further includes a phosphor PAM of a sixth color dispersed in the light adjustment layer LCL together with the phosphor PY of the fifth color, the phosphor PR of the first color, and the phosphor PG of the second color, and redundant descriptions will not be provided in the following description.

The sixth color may correspond to the wavelength band between the wavelength band of the first color and the wavelength band of the fifth color.

As described above, the first color may be red having a wavelength band of approximately 620 nm to 750 nm, and the fifth color may be yellow having a main peak wavelength of approximately 570 nm to 590 nm. In this case, the sixth color may be amber (or orange) corresponding to a wavelength band of approximately 590 nm to 620 nm between the wavelength band of the first color and the wavelength band of the fifth color.

The phosphor PAM of the sixth color may be selected as Alpha-SiAlON and/or Sr₃SiO₅:Eu²⁺.

Accordingly, the fourth light emitting unit EP4d according to the fourth embodiment may emit the light of the fourth color (e.g., white) generated by mixing the light of the third color (e.g., blue) from the third light emitting element LE3, the light of the second color (e.g., green) from the phosphor PG of the second color, the light of the fifth color (e.g., yellow) from the phosphor PY of the fifth color, the light of the sixth color (e.g., amber) from the phosphor PAM of the sixth color, and the light of the first color (e.g., red) from the phosphor PR of the first color.

For example, the light of the fourth color emitted from the fourth light emitting unit EP4d of the fourth embodiment may have five main peak wavelengths including a wavelength band of approximately 400 nm to 420 nm corresponding to the third color, a wavelength band of approximately 560 nm to 600 nm corresponding to the fifth color, a wavelength band of approximately 620 nm to 750 nm corresponding to the first color, a wavelength band of approximately 490 nm to 570 nm corresponding to the second color, and a wavelength band of approximately 590 nm to 620 nm corresponding to the sixth color.

Therefore, the light of the fourth color from the fourth light emitting unit EP4d of the fourth embodiment may exhibit a higher CRI compared to the light of the fourth color from the fourth light emitting unit EP4c of the third embodiment.

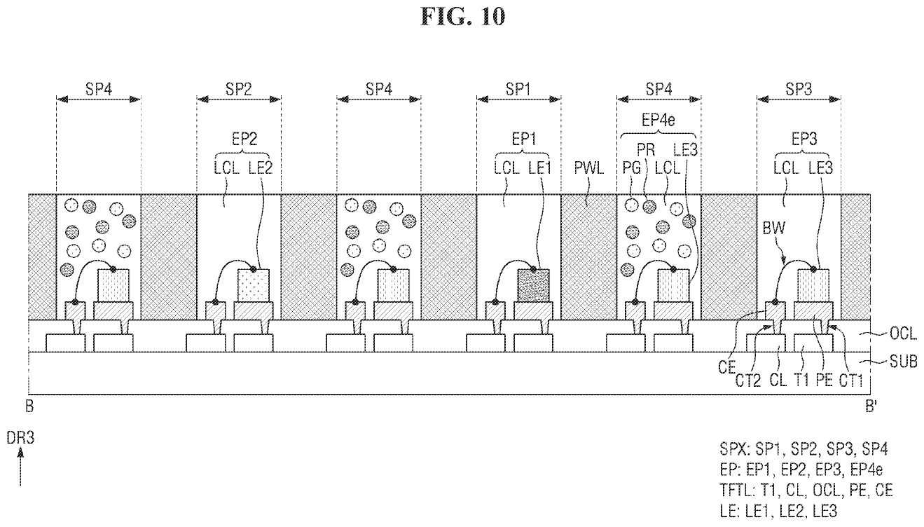

FIG. 10 is a cross-sectional view showing a display device taken along line B-B′ of FIG. 3 according to a fifth embodiment.

Referring to FIG. 10, the display device according to the fifth embodiment is the same as the display device according to the third embodiment shown in FIG. 8 except that the fourth light emitting unit EP4e does not include the phosphor PY of the fifth color, redundant descriptions will not be provided in the following description.

For example, the fourth light emitting unit EP4e of the fifth embodiment includes the phosphor PR of the first color and the phosphor PG of the second color dispersed in the light adjustment layer LCL.

For example, the phosphor PR of the first color included in the fourth light emitting unit EP4e according to the fifth embodiment may be selected as (Sr, Ca)AlSiN₃:Eu²⁺.

The phosphor PG of the second color included in the fourth light emitting unit EP4e of the fifth embodiment may be selected as Lu₃Al₅O₁₂:Ce³⁺ and/or Y₃(Al, Ga)₅O₁₂:Ce³⁺.

Accordingly, the fourth light emitting unit EP4e according to the fifth embodiment may emit the light of the fourth color (e.g., white) generated by mixing the light of the third color (e.g., blue) from the third light emitting element LE3, the light of the second color (e.g., green) from the phosphor PG of the second color, and the light of the first color (e.g., red) from the phosphor PR of the first color.

For example, the light of the fourth color emitted from the fourth light emitting unit EP4e of the fifth embodiment may have three main peak wavelengths including a wavelength band of approximately 400 nm to 420 nm corresponding to the third color, a wavelength band of approximately 490 nm to 570 nm corresponding to the second color, and a wavelength band of 620 nm to 750 nm corresponding to the first color.

Accordingly, the light of the fourth color from the fourth light emitting unit EP4e of the fifth embodiment, which is generated by mixing the first color, the second color, and the third color and exhibits a CRI of approximately 80 to 90, may be used as a lighting.

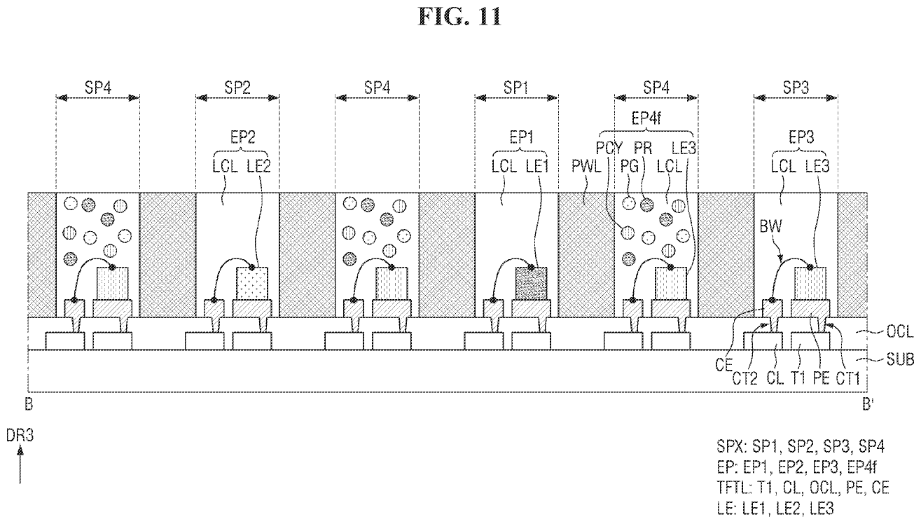

FIG. 11 is a cross-sectional view showing a display device taken along line B-B′ of FIG. 3 according to a sixth embodiment.

Referring to FIG. 11, the display device according to the sixth embodiment is the same as the display device according to the fifth embodiment shown in FIG. 10 except that a fourth light emitting unit EP4f further includes a phosphor PCY of a seventh color, and redundant descriptions will not be provided in the following description.

The seventh color may correspond to the wavelength band between the wavelength band of the second color and the wavelength band of the third color.

As described above, the second color may be green having a wavelength band of approximately 490 nm to 570 nm, and the third color may be blue having a wavelength band of approximately 400 nm to 420 nm. Here, the main peak wavelength of the third color may be approximately 430 nm to 480 nm. Further, the main peak wavelength of the second color may be approximately 520 nm to 570 nm. In this case, the seventh color may be cyan corresponding to a wavelength band of approximately 480 nm to 520 nm.

For example, the phosphor PCY of the seventh color included in the fourth light emitting unit EP4f of the sixth embodiment may be selected as (Ba, Mg)Si₂O₂N₂:Eu²⁺ and/or (Ba, Mg)₃Si₆O₃N₈:Eu²⁺.

Accordingly, the fourth light emitting unit EP4f according to the sixth embodiment may emit the light of the fourth light (e.g., white) generated by mixing the light of the third color (e.g., blue) from the third light emitting element LE3, the light of the seventh color (e.g., cyan) from the phosphor PCY of the seventh color, the light of the second color (e.g., green) from the phosphor PG of the second color, and the light of the first color (e.g., red) from the phosphor PR of the first color.

For example, the light of the fourth color emitted from the fourth light emitting unit EP4f of the sixth embodiment may have four main peak wavelengths including a wavelength band of approximately 430 nm to 480 nm corresponding to the third color, a wavelength band of approximately 480 nm to 520 nm corresponding to the seventh color, a wavelength band of approximately 520 nm to 570 nm corresponding to the second color, and a wavelength band of approximately 620 nm to 750 nm corresponding to the first color.

Therefore, the light of the fourth color from the fourth light emitting unit EP4f of the sixth embodiment may exhibit a higher CRI compared to the light of the fourth color from the fourth light emitting unit EP4e of the fifth embodiment.

For example, the light of the fourth color from the fourth light emitting unit EP4f of the sixth embodiment, which is generated by mixing the first color, the second color, the seventh color, and the third color, may exhibit a CRI of approximately 90 to 99. Accordingly, it may be used as an outdoor lighting for sport events and/or the like.

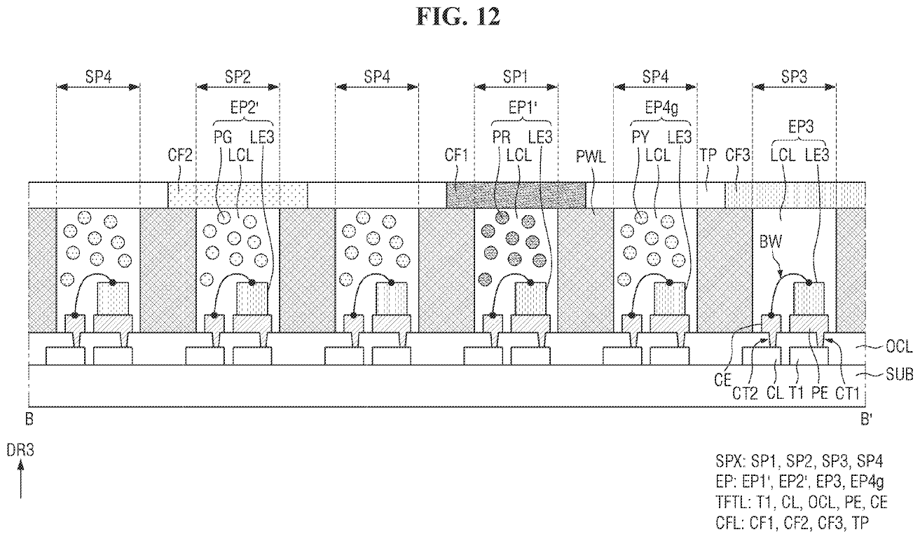

FIG. 12 is a cross-sectional view showing a display device taken along line B-B′ of FIG. 3 according to a seventh embodiment.

Referring to FIG. 12, the display device according to the seventh embodiment is the same as the display devices according to the first to sixth embodiments except that each of the plurality of light emitting units EP includes the third light emitting element LE3, a first light emitting unit EP1′ further includes the phosphor PR of the first color dispersed in the light adjustment layer LCL, and a second light emitting unit EP2′ further includes the phosphor PG of the second color dispersed in the light adjustment layer LCL, and redundant descriptions will not be provided.

For example, in accordance with the seventh embodiment, the first light emitting unit EP1′ and the second light emitting unit EP2′ include the third light emitting element LE3 emitting the light of the third color similarly to the third light emitting unit EP3 without including the first light emitting element LE1 and the second light emitting element LE2, respectively.

Instead, the first light emitting unit EP1′ further includes the phosphor PR of the first color that converts at least a part of the light of the third color from the third light emitting element LE3 to the light of the first color in order to emit the light of the first color corresponding to the first sub-pixel SP1.

Similarly, the second light emitting unit EP2′ further includes the phosphor PG of the second color that converts at least a part of the light of the third color from the third light emitting element LE3 to the light of the second color in order to emit the light of the second color corresponding to the second sub-pixel SP2.

As described above, in accordance with the seventh embodiment, all of the first light emitting unit EP1′, the second light emitting unit EP2′, the third light emitting unit EP3, and a fourth light emitting unit EP4g include the third light emitting element LE3 emitting the light of the third color having the lowest wavelength band among the first color, the second color, and the third color.

Accordingly, it is unnecessary to provide multiple types (or kinds) of light emitting elements emitting lights of different wavelength bands, which may be advantageous in facilitating the process and reducing a manufacturing cost.

The first light emitting unit EP1′ of the seventh embodiment further includes the phosphor PR of the first color dispersed in the light adjustment layer LCL, in addition to the third light emitting element LE3 emitting the light of the third color, in order to emit the light of the first color having a wavelength band higher than that of the third color.

The phosphor PR of the first color converts a part of the light of the third color (e.g., blue light) emitted from the third light emitting element LE3 to the light of the first color (e.g., red) having a wavelength band higher than that of the third color.

For example, the phosphor PR of the first color may be selected as at least one of (Sr, Ca)AlSiN₃:Eu²⁺, K₂SiF₆:Mn⁴⁺, Na₂SiF₆:Mn⁴⁺, KNaSiF₆:Mn⁴⁺, K₂GeF₆:Mn⁴⁺, K₂TiF₆:Mn⁴⁺, Mg₄GeO₃F:Mn⁴⁺, 3.5MgO·0.5MgF₂·GeO₂:Mn⁴⁺, Sr(Li₂Al₂O₂N₂):Eu²⁺, (Sr, Ba)₂Si₅N₈:Eu²⁺, BaMgAl₁₀O₁₇:Mn⁴⁺, Mg²⁺, CaS:Eu²⁺, InP (QDs), and CsPbI₃ (Perovskite QDs).

The second light emitting unit EP2′ of the seventh embodiment further includes the phosphor PG of the second color dispersed in the light adjustment layer LCL, in addition to the third light emitting element LE3 emitting the light of the third color, in order to emit the light of the second color having a wavelength band higher than that of the third color.

The phosphor PG of the second color converts a part of the light of the third color (e.g., blue light) emitted from the third light emitting element LE3 to the light of the second color (e.g., green) having a wavelength band higher than that of the third color.

For example, the phosphor PG of the second color may be selected as at least one of (Sr, Ba, Mg)₂SiO₄:Eu²⁺, Lu₃(Al,Ga)₅O₁₂:Ce³⁺, Ba₃Si₆O₁₂N₂:Eu²⁺, SrGa₂S₄:Eu²⁺, Gamma AlON:Eu²⁺, InP (QDs), and/or CsPbBr₃ (QDs)(Perovskite QDs).

The fourth light emitting unit EP4g according to the seventh embodiment may further include one or more types (or kinds) of phosphors dispersed in the light adjustment layer LCL, in addition to the third light emitting element LE3 emitting the light of the third color, in order to emit the light of the fourth color having a wavelength band wider than that of the third color.

For example, the fourth light emitting unit EP4g of the seventh embodiment may further include the phosphor PY of the fifth color, similarly to the first embodiment of FIG. 5.

In some embodiments, the fourth light emitting unit EP4g according to the seventh embodiment may further include at least one type (or kind) of phosphor, similarly to the fourth light emitting units EP4b to EP4f of the second to sixth embodiments shown in FIGS. 7 to 11.

For example, the fourth light emitting unit EP4g of the seventh embodiment may further include the phosphor PY of the fifth color and the phosphor PR of the first color, similarly to the fourth light emitting unit EP4b of the second embodiment shown in FIG. 7.

In some embodiments, the fourth light emitting unit EP4g of the seventh embodiment may further include the phosphor PY of the fifth color, the phosphor PR of the first color, and the phosphor PG of the second color, similarly to the fourth light emitting unit EP4c of the third embodiment shown in FIG. 8.

In some embodiments, the fourth light emitting unit EP4g of the seventh embodiment may further include the phosphor PY of the fifth color, the phosphor PR of the first color, the phosphor PG of the second color, and the phosphor PAM of the sixth color, similarly to the fourth light emitting unit EP4d of the fourth embodiment shown in FIG. 9.

In some embodiments, unlike the embodiments of FIG. 12, the fourth light emitting unit EP4g of the seventh embodiment may further include the phosphor PR of the first color and the phosphor PG of the second color, similarly to the fourth light emitting unit EP4e of the fifth embodiment shown in FIG. 10.

In some embodiments, the fourth light emitting unit EP4g of the seventh embodiment may further include the phosphor PR of the first color, the phosphor PG of the second color, and the phosphor PCY of the seventh color, similarly to the fourth light emitting unit EP4f of the sixth embodiment shown in FIG. 11.

The display device according to the seventh embodiment may further include a color filter layer CFL provided on the plurality of light emitting units EP.

The color filter layer CFL may include a first color filter CF1 corresponding to the first sub-pixel SP1, a second color filter CF2 corresponding to the second sub-pixel SP2, a third color filter CF3 corresponding to the third sub-pixel SP3, and a transmitting pattern TP corresponding to the fourth sub-pixel SP4.

The first color filter may contain a dye or a pigment that selectively transmits light in a wavelength band corresponding to the first color.

The second color filter may contain a dye or pigment that selectively transmits light in a wavelength band corresponding to the second color.

The third color filter may contain a dye or a pigment that selectively transmits light in a wavelength band corresponding to the third color.

The transmitting pattern TP may be made of a relatively (e.g., suitably) transparent material.

Due to the color filter layer CFL, even if the first sub-pixel SP1 corresponding to the first color and the second sub-pixel SP2 corresponding to the second color include the third light emitting element LE3 emitting the light of the third color, it is possible to prevent or reduce the deterioration in the color purity of the light emitted from each of the plurality of sub-pixels SPX.

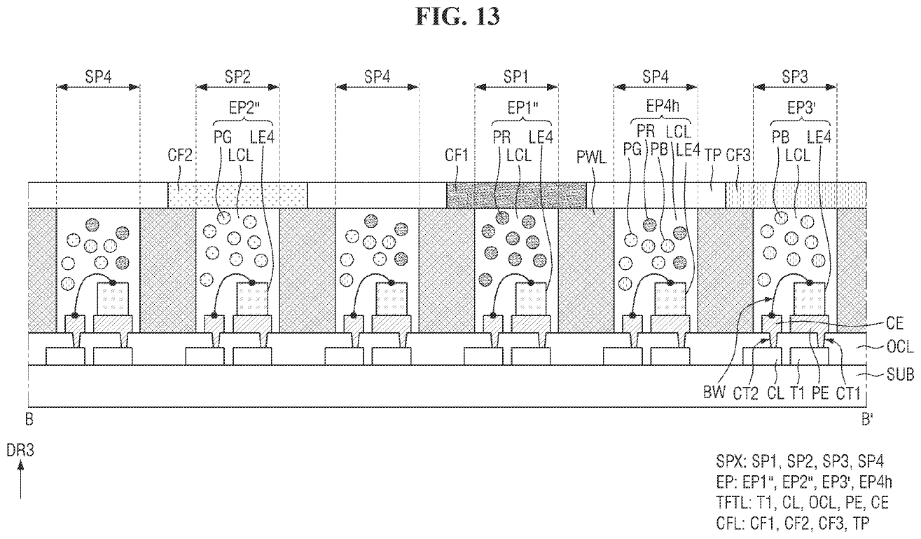

FIG. 13 is a cross-sectional view showing a display device taken along line B-B′ of FIG. 3 according to an eighth embodiment.

Referring to FIG. 13, the display device according to the eighth embodiment is the same as the display device according to the seventh embodiment except that the plurality of light emitting units EP include a fourth light emitting element LE4 emitting light of a wavelength band lower than that of the third color, and a third light emitting unit EP3′ further includes a phosphor PB of the third color dispersed in the light adjustment layer LCL, and redundant descriptions will not be provided.

For example, in accordance with the eighth embodiment, each of the plurality of light emitting units EP includes the fourth light emitting element LE4 emitting light (e.g., ultraviolet (UV) light) of a wavelength band lower than that of the third color. For example, the fourth light emitting element LE4 may emit ultraviolet light having a wavelength band of approximately 400 nm to 420 nm.

A first light emitting unit EP1″ according to the eighth embodiment may include the phosphor PR of the first color that is dispersed in the light adjustment layer LCL and converts at least a part of the light from the fourth light emitting element LE4 to the light of the first color (e.g., red).

For example, the phosphor PR of the first color may be selected as at least one of Mg₄GeO₃F:Mn⁴⁺, 3.5MgO·0.5MgF₂·GeO₂:Mn⁴⁺, K₂(Si, Ge, Ti)SiF₆:Mn⁴⁺, and (Sr, Ca)AlSiN₃:Eu²⁺.

A second light emitting unit EP2″ of the eighth embodiment may include the phosphor PG of the second color that is dispersed in the light adjustment layer LCL and converts at least a part of the light from the fourth light emitting element LE4 to the light of the second color (e.g., green).

For example, the phosphor PG of the second color may be selected as at least one of Beta-SiAlON:Eu²⁺, SrGa₂S₄:Eu²⁺, BaAlMg₁₀O₁₇:Eu²⁺, Mn²⁺, (Sr, Ba, Mg)₂SiO₄:Eu²⁺, and (Lu,Y)₃(Al, Ga)₅O₁₂:Ce³⁺.

A third light emitting unit EP3′ of the eighth embodiment includes the phosphor PB of the third color that is dispersed in the light adjustment layer LCL and converts at least a part of the light of the fourth light emitting element LE4 to the light of the third color (e.g., blue).

For example, the phosphor PB of the third color may be selected as BaAlMg₁₀O₁₇:Eu²⁺.

The fourth light emitting unit EP4g of the eighth embodiment may include the phosphor PR of the first color, the phosphor PG of the second color, and the phosphor PB of the third color that are dispersed in the light adjustment layer LCL.

Accordingly, the fourth light emitting unit EP4g may emit the light of the fourth color generated by mixing the light of the first color from the phosphor PR of the first color, the light of the second color from the phosphor PG of the second color, and the light of the third color from the phosphor PB of the third color.

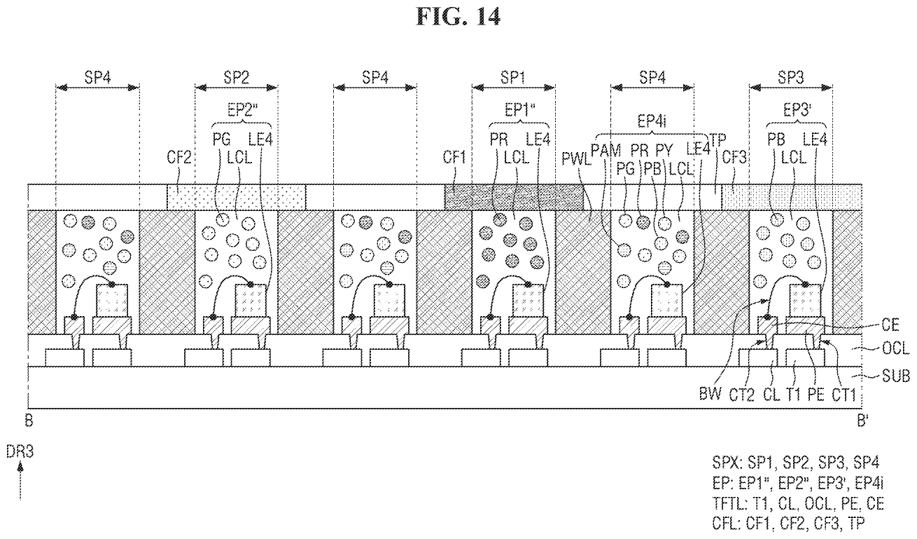

FIG. 14 is a cross-sectional view showing a display device taken along line B-B′ of FIG. 3 according to a ninth embodiment.

Referring to FIG. 14, the display device according to the ninth embodiment is the same as the display device according to the eighth embodiment shown in FIG. 13 except that a fourth light emitting unit EP4i further includes the phosphor PY of the fifth color and the phosphor PAM of the sixth color dispersed in the light adjustment layer LCL together with the phosphor PR of the first color, the phosphor PG of the second color, and the phosphor PB of the fifth color, and redundant descriptions will not be provided in the following description.

Because the fourth light emitting unit EP4i according to the ninth embodiment further includes the phosphor PY of the fifth color and the phosphor PAM of the sixth color, the light of the fourth color from the fourth light emitting unit EP4i according to the ninth embodiment may exhibit a higher CRI compared to the light of the fourth color from a fourth light emitting unit EP4h of the eighth embodiment.

As described above with reference to FIG. 3, in accordance with one or more embodiments, the arrangement pattern of the plurality of sub-pixels SPX includes the first pixel columns PXL11 and PXL21 in which the first sub-pixel SP1, the fourth sub-pixel SP4, the third sub-pixel SP3, and the fourth sub-pixel SP4 are repeatedly arranged side by side in one direction (e.g., in the directions DR1 and DR2, respectively), and the second pixel columns PXL12 and PXL22 in which the second sub-pixel SP2 and the fourth sub-pixel SP4 are repeatedly arranged side by side in one direction (e.g., in the directions DR1 and DR2, respectively). Here, the first pixel column PXL11 and the second pixel column PXL12 alternate with each other in the second direction DR2, and the first pixel column PXL21 and the second pixel column PXL22 alternate each other in the first direction DR1.

In the other direction (e.g., the other one of the directions DR1 and DR2), each of the first sub-pixel SP1 and the third sub-pixel SP3 of the first pixel columns PXL11 and PXL21 is adjacent to the fourth sub-pixel SP4 of the second pixel columns PXL12 and PXL22. Further, in the other direction (e.g., the other one of the directions DR1 and DR2), the second sub-pixel SP2 of the second pixel columns PXL12 and PXL22 is adjacent to the fourth sub-pixel SP4 of the first pixel columns PXL11 and PXL21.

For example, in accordance with the embodiments, in each of the first direction DR1 and the second direction DR2, both sides of each of the first sub-pixel SP1, the second sub-pixel SP2, and the third sub-pixel SP3 corresponding to different wavelength bands of the visible light may be adjacent to the fourth sub-pixel SP4 corresponding to the entire wavelength band of the visible light.

Here, there may be provided the plurality of sub-pixels PX_E1 and PX_E2, each including eight sub-pixels adjacent to each other in one direction (e.g., any one of the directions DR1 and DR2) and/or in the other direction (e.g., the other one of the directions DR1 and DR2) among the plurality of sub-pixels SPX.

Each of the plurality of pixels PX_E1 and PX_E2 may include at least one first sub-pixel SP1, at least one second sub-pixel SP2, and at least one third sub-pixel SP3 to serve as a basic unit for displaying various colors by mixing the first color, the second color, and the third color, and may further include at least one fourth sub-pixel SP4 to display the light of the fourth color.

For example, each of the plurality of pixels PX_E1 and PX_E2 according to the embodiments may include one first sub-pixel SP1, one third sub-pixel SP3, and two fourth sub-pixels SP4 arranged side by side in the first pixel columns PXL11 and PXL21, respectively, and two second sub-pixels SP2 and two fourth sub-pixels SP4 arranged side by side in the second pixel columns PXL12 and PXL22, respectively.

However, the illustration of FIG. 3 is only an example of the arrangement pattern of the plurality of sub-pixels SPX according to the embodiments, and the arrangement pattern of the plurality of sub-pixels SPX according to the embodiments is not limited to the one shown in FIG. 3.

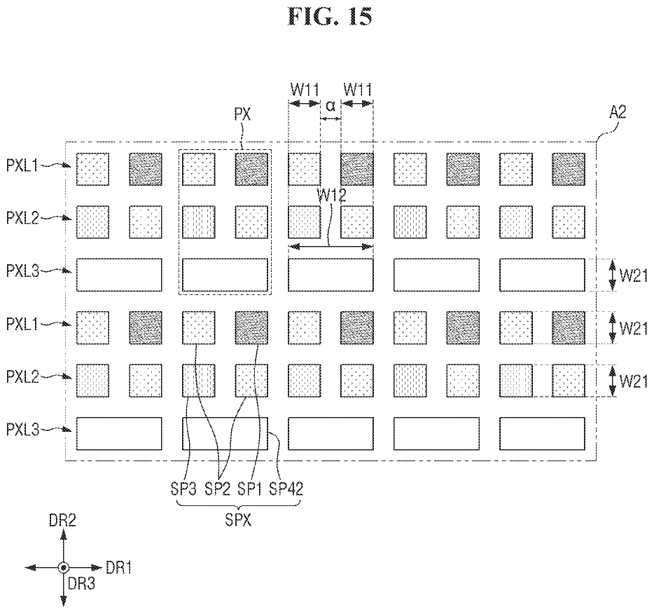

Hereinafter, other examples of the arrangement pattern of the plurality of sub-pixels SPX according to the embodiments will be described with reference to FIGS. 15 to 23.

FIG. 15 is a plan view showing a second example of part A of FIG. 2.

Referring to FIG. 15, the arrangement pattern of the plurality of sub-pixels SPX according to a second example A2 may include a first pixel column PXL1 in which the first sub-pixel SP1 and the second sub-pixel SP2 are alternately arranged side by side in the first direction DR1, a second pixel column PXL2 in which the second sub-pixel SP2 and the third sub-pixel SP3 are alternately arranged side by side in the first direction DR1, and a third pixel column PXL3 in which fourth sub-pixels SP42 are arranged side by side in the first direction DR1.

In the second direction DR2 intersecting the first direction DR1, the first pixel column PXL1 and the second pixel column PXL2 are adjacent to each other.

Further, in the second direction DR2, the first sub-pixel SP1 of the first pixel column PXL1 is adjacent to the second sub-pixel SP2 of the second pixel column PXL2, and the third sub-pixel SP3 of the second pixel column PXL2 is adjacent to the second sub-pixel SP2 of the first pixel column PXL1.

The third pixel column PXL3 may be provided between one side (e.g., the upper side of FIG. 15) of the first pixel column PXL1 in the second direction DR2 and the other side (e.g., the lower side of FIG. 15) of the second pixel column PXL2 in the second direction DR2.

For example, the fourth sub-pixel SP42 of the third pixel column PXL3 may be adjacent to one second sub-pixel SP2 and one third sub-pixel SP3 in the second pixel column PXL2 on one side (e.g., the upper side of FIG. 15) of the second direction DR2, and may be adjacent to one first sub-pixel SP1 and one second sub-pixel SP2 in the first pixel column PXL1 on the other side (e.g., the lower side of FIG. 15) of the second direction DR2.

However, this is only an example, and the second example is not limited to the illustration of FIG. 15. For example, in accordance with the second example, the third pixel column PXL3 may be provided between one side (e.g., the upper side of FIG. 15) of the second pixel column PXL2 in the second direction DR2 and the other side (e.g., the lower side of FIG. 15) of the first pixel column PXL1 in the second direction DR2.

For example, each of the fourth sub-pixels SP42 may be adjacent to each of the first sub-pixel SP1, the third sub-pixel SP3, and the second sub-pixel SP2 in the second direction DR2.

The first sub-pixel SP1, the second sub-pixel SP2, and the third sub-pixel SP3 included in the first pixel column PXL1 or the second pixel column PXL2 may have the same set or predetermined first width W11 in the first direction DR1. In this case, the fourth sub-pixel SP42 of the third pixel column PXL3 may have a second width W12 greater than twice the first width W11 in the first direction DR1.

Here, the second width W12 may correspond to the sum of the double value of the first width W11 (2*W11) and a gap a between the sub-pixels (W12=2*W11+α).

In accordance with the second example A2, each of the plurality of sub-pixels SPX may have the same set or predetermined third width W21 in the second direction DR2.

In accordance with the second example A2, there may be provided a plurality of pixels PX, each including five sub-pixels adjacent to each other in the first direction DR1 and/or the second direction DR2 among the plurality of sub-pixels SPX. Each of the plurality of pixels PX includes at least one first sub-pixel SP1, at least one second sub-pixel SP2, and at least one third sub-pixel SP3, and at least one fourth sub-pixel SP42 to serve as the basic unit for displaying various colors including the fourth color.

For example, each of the plurality of pixels PX according to the second example A2 may include one first sub-pixel SP1 and one second sub-pixel SP2 adjacent to each other in the first pixel column PXL1, one third sub-pixel SP3 and one second sub-pixel SP2 adjacent to each other in the second pixel column PXL2, and one fourth sub-pixel SP42 in the third pixel columns PXL3.

In accordance with this second example A2, compared to the first example A1 (see FIG. 3), the number of fourth sub-pixels SP42 is reduced, so that the lines for displaying the light of the fourth color may be reduced. Accordingly, the increase in the width of the non-display area NDA due to the addition of the fourth sub-pixel SP42 may be reduced.

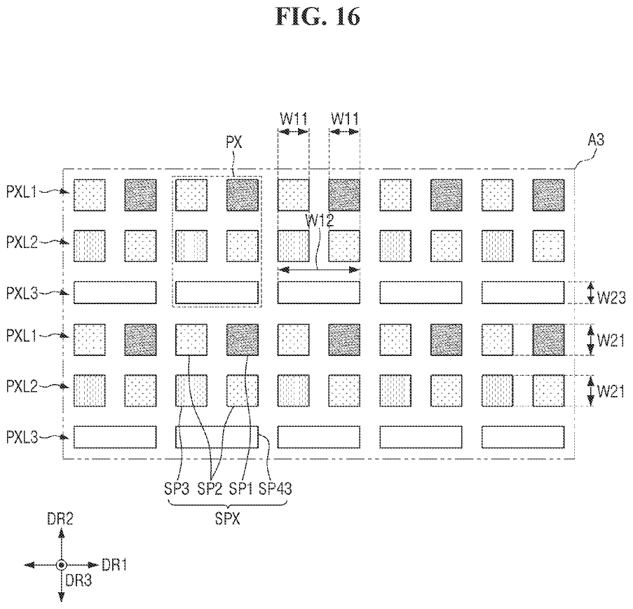

FIG. 16 is a plan view showing a third example of part A of FIG. 2.

Referring to FIG. 16, the arrangement pattern of the plurality of sub-pixels SPX according to a third example A3 is the same as that according to the second example A2 shown in FIG. 15, except that each of the first sub-pixel SP1, the second sub-pixel SP2, and the third sub-pixel SP3 included in the first pixel column PXL1 and the second pixel column PXL2 has the third width W21 in the second direction DR2, and a fourth sub-pixel SP43 of the third pixel column PXL3 has a fourth width W23 smaller than the third width W21 in the second direction DR2. Redundant descriptions will not be provided.

In accordance with this third example A3, because the width of the fourth sub-pixel SP43 in the second direction DR2 is reduced, the decrease in the width of the first sub-pixel SP1, the second sub-pixel SP2, and the third sub-pixel SP3 due to the addition of the fourth sub-pixel SP43 may be reduced.

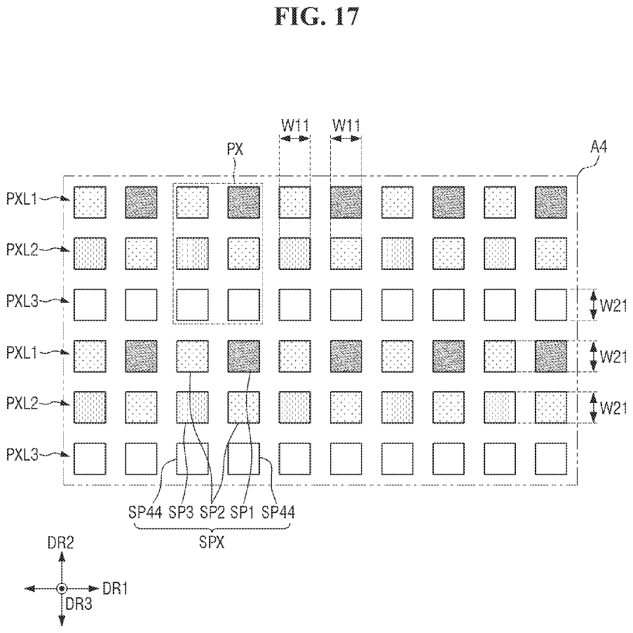

FIG. 17 is a plan view showing a fourth example of part A of FIG. 2.

Referring to FIG. 17, the arrangement pattern of the plurality of sub-pixels SPX according to a fourth example A4 is the same as that according to the second example A2 shown in FIG. 15, except that a fourth sub-pixel SP44 of the third pixel column PXL3 has the first width W11 in the first direction DR1 and has the second width W21 in the second direction DR2, similarly to the first sub-pixel SP1, the second sub-pixel SP2, and the third sub-pixel SP3. Redundant descriptions will not be provided.

For example, in accordance with the fourth example A4, the first sub-pixel SP1, the second sub-pixel SP2, the third sub-pixel SP3, and the fourth sub-pixel SP44 may have the same set or predetermined first width W11 in the first direction DR1.

Accordingly, in accordance with the fourth example A4, the fourth sub-pixel SP44 of the third pixel column PXL3 may be adjacent to any one of the second sub-pixel SP2 and the third sub-pixel SP3 of the second pixel column PXL2 on one side (e.g., the upper side of FIG. 17) of the second direction DR2, and may be adjacent to any one of the first sub-pixel SP1 and the second sub-pixel SP2 on the other side (e.g., the lower side of FIG. 17) of the second direction DR2.

Accordingly, each pixel PX includes two fourth sub-pixels SP44 having the same width and, thus, the grayscale expression of the light of the fourth color may be variously suitably divided.

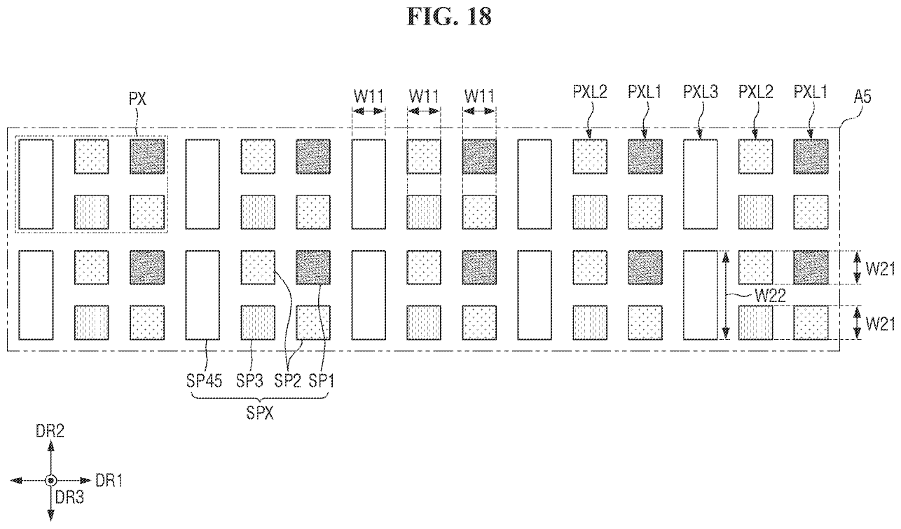

FIG. 18 is a plan view showing a fifth example of part A of FIG. 2.

Referring to FIG. 18, the arrangement pattern of the plurality of sub-pixels SPX according to a fifth example A5 is the same as that according to the second example A2 shown in FIG. 15, except that the first direction DR1 and the second direction DR2 are applied reversely (e.g., the directions of the sub-pixel arrangement are reversed), and redundant descriptions will not be provided.

For example, in accordance with the fifth example A5, the first pixel column PXL1 may include the first sub-pixel SP1 and the second sub-pixel SP2 alternately arranged side by side in the second direction DR2, the second pixel column PXL2 may include the second sub-pixel SP2 and the third sub-pixel SP3 alternately arranged side by side in the second direction DR2, the third pixel column PXL3 may include the fourth sub-pixels arranged side by side in the second direction DR2, and the first pixel column PXL1, the second pixel column PXL2, and the third pixel column PXL3 may be adjacent to each other in the first direction DR1.

The third pixel column PXL3 may be provided between one side (e.g., the left side of FIG. 18) of the first pixel column PXL1 and the other side (e.g., the right side of FIG. 18) of the second pixel column PXL2 in the first direction DR1.

A fourth sub-pixel SP45 of the third pixel column PXL3 may be adjacent to the first sub-pixel SP1 and the second sub-pixel SP2 of the first pixel column PXL1 on the other side (e.g., the left side of FIG. 18) of the first direction DR1, and may be adjacent to the third sub-pixel SP3 and the second sub-pixel SP2 of the second pixel column PXL2 on one side (e.g., the right side of FIG. 18) of the first direction DR1.

Further, in accordance with the fifth example A5, the first sub-pixel SP1, the second sub-pixel SP2, and the third sub-pixel SP3 included in the first pixel column PXL1 or the second pixel column PXL2 may have the same set or predetermined first width W21 in the second direction DR2. In this case, the fourth sub-pixel SP45 of the third pixel column PXL3 may have a second width W22 greater than twice the first width W21 in the second direction DR2.

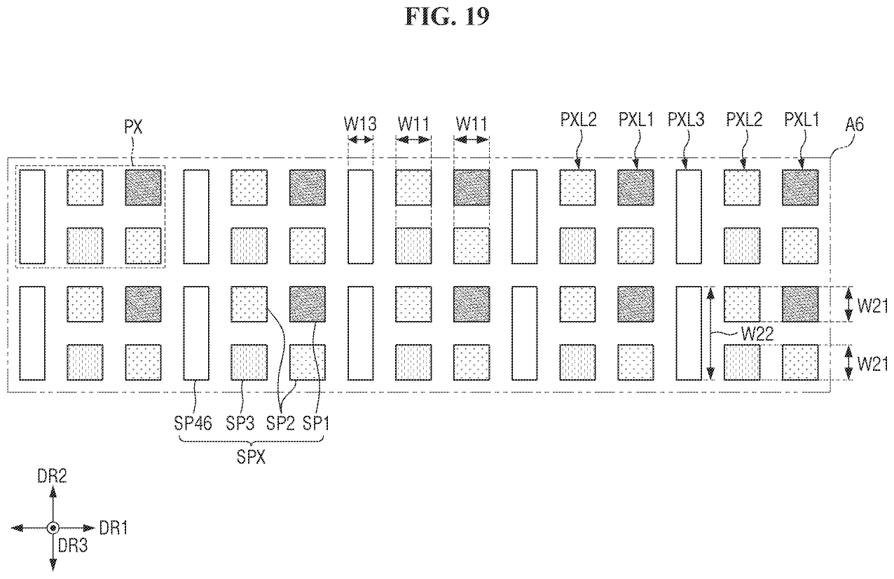

FIG. 19 is a plan view showing a sixth example of part A of FIG. 2.

Referring to FIG. 19, the arrangement pattern of the plurality of sub-pixels SPX according to a sixth example A6 is the same as that according to the third example A3 shown in FIG. 16 except that the first direction DR1 and the second direction DR2 are applied reversely, and redundant descriptions will not be provided.

For example, in accordance with the sixth example A6, the first sub-pixel SP1, the second sub-pixel SP2, and the third sub-pixel SP3 included in the first pixel column PXL1 and the second pixel column PXL2 may have the third width W11 in the first direction DR1, and the fourth sub-pixel SP46 of the third pixel column PXL3 may have a fourth width W13 smaller than the third width W11 in the first direction DR1.

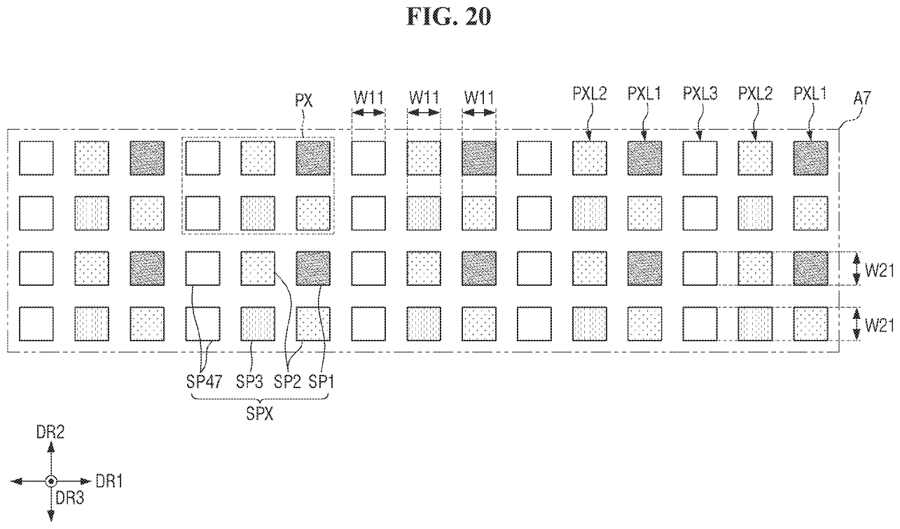

FIG. 20 is a plan view showing a seventh example of part A of FIG. 2.

Referring to FIG. 20, the arrangement pattern of the plurality of sub-pixels SPX according to a seventh example A7 is the same as that according to the fourth example A4 shown in FIG. 17 except that the first direction DR1 and the second direction DR2 are applied reversely, and redundant descriptions will not be provided.

For example, in accordance with the seventh example A7, the fourth sub-pixel SP47 of the third pixel column PXL3 may be adjacent to any one of the first sub-pixel SP1 and the second sub-pixel SP2 of the first pixel column PXL1 on the other side (e.g., the left side of FIG. 18) of the first direction DR1, and may be adjacent to any one of the third sub-pixel SP3 and the second sub-pixel SP2 of the second pixel column PXL2 on one side (e.g., the right side of FIG. 18) of the first direction DR1.

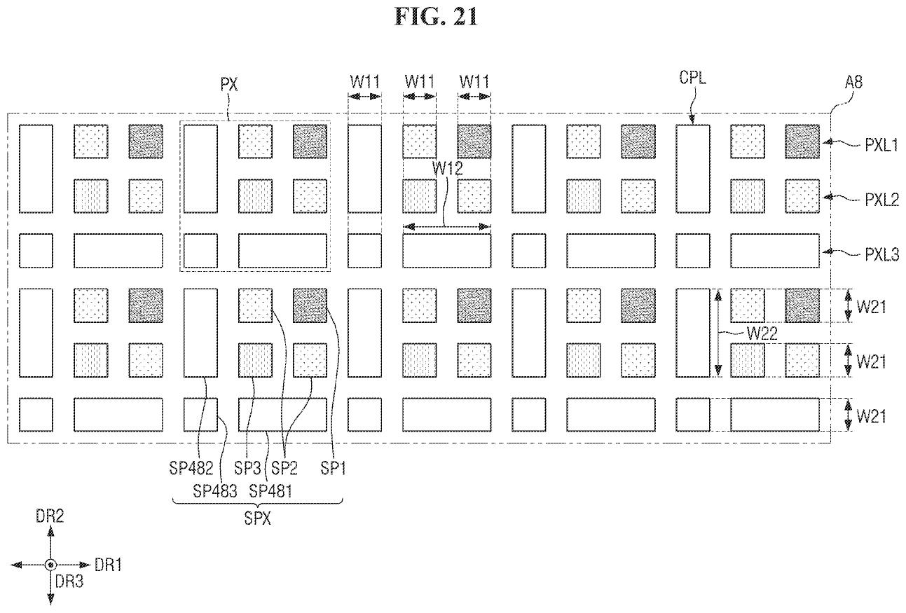

FIG. 21 is a plan view showing an eighth example of part A of FIG. 2.

Referring to FIG. 21, the arrangement pattern of the plurality of sub-pixels SPX according to an eighth example A8 is the same as that according to the second example A2 shown in FIG. 15 except that an intersection column CPL in which the fourth sub-pixels SP4 are arranged side by side in the second direction DR2 is further included, and redundant descriptions will not be provided.

For example, the arrangement pattern of the plurality of sub-pixels SPX according to the eighth example A8 includes the first pixel column PXL1, the second pixel column PXL2, and the third pixel column PXL3 alternately arranged with each other in the second direction DR2, and the intersection column CPL including fourth sub-pixels SP482 and SP483 arranged in the second direction DR2.

The first pixel column PXL1 includes the first sub-pixel SP1 and the second sub-pixel SP2 alternately arranged side by side in the first direction DR1.

The second pixel column PXL2 includes the second sub-pixel SP2 and the third sub-pixel SP3 alternately arranged side by side in the first direction DR1.

The first pixel column PXL1 and the second pixel column PXL2 are adjacent to each other in the second direction DR2. For example, the first sub-pixel SP1 of the first pixel column PXL1 is adjacent to the second sub-pixel SP2 of the second pixel column PXL2 in the second direction DR2, and the third sub-pixel SP3 of the second pixel column PXL2 is adjacent to the second sub-pixel SP2 of the first pixel column PXL1 in the second direction DR2.

The third pixel column PXL3 includes fourth sub-pixels SP481 arranged side by side in the first direction DR1.

The third pixel column PXL3 may be adjacent to the first pixel column PXL1 on one side (e.g., the lower side of FIG. 21) of the second direction DR2, and may be adjacent to the second pixel column PXL2 on the other side (e.g., the upper side of FIG. 21) of the second direction DR2.

Accordingly, each of the fourth sub-pixels SP481 of the third pixel column PXL3 may be adjacent to the first sub-pixel SP1 and the second sub-pixel SP2 of the first pixel column PXL1 on one side (e.g., the lower side of FIG. 21) of the second direction DR2. Further, each of the fourth sub-pixels SP481 of the third pixel column PXL3 may be adjacent to the second sub-pixel SP2 and the third sub-pixel SP3 of the second pixel column PXL2 on the other side (e.g., the upper side of FIG. 21) of the second direction DR2.

Each of the first sub-pixel SP1, the second sub-pixel SP2, and the third sub-pixel SP3 included in the first pixel column PXL1 and the second pixel column PXL2 may have the set or predetermined first width W11 in the first direction DR1, and the fourth sub-pixel SP481 of the third pixel column PXL3 may have the second width W12 greater than twice the first width W11 in the first direction DR1.

Each of the first sub-pixel SP1, the second sub-pixel SP2, and the third sub-pixel SP3 included in the first pixel column PXL1 and the second pixel column PXL2 may have the same set or predetermined third width W21 in the second direction DR2.

Similarly, the fourth sub-pixel SP481 of the third pixel column PXL3 may also have the third width W21 in the second direction DR2.

The fourth sub-pixel SP482 that is a part of the intersection column CPL is adjacent to the first pixel column PXL1 and the second pixel column PXL2 (e.g., to the sub-pixels in the first pixel column PXL1 and the second pixel column PXL2) in the first direction DR1, and the fourth sub-pixel SP483 that is another part of the intersection column CPL is adjacent to the third pixel column PXL3 (e.g., to the sub-pixels in the third pixel column PXL3) in the first direction DR1.

For example, the intersection column CPL has a structure in which the fourth sub-pixel SP482 corresponding to the first pixel column PXL1 and the second pixel column PXL2 and the fourth sub-pixel SP483 corresponding to the third pixel column PXL3 are alternately arranged in the second direction DR2.

For example, the fourth sub-pixel SP482 that is a part of the intersection column CPL may be adjacent to the first sub-pixel SP1 of the first pixel column PXL1 and the second sub-pixel SP2 of the second pixel column PXL2 on one side (e.g., the left side of FIG. 21) of the first direction DR1. Further, the fourth sub-pixel SP482 that is a part of the intersection column CPL may be adjacent to the second sub-pixel SP2 of the first pixel column PXL1 and the third sub-pixel SP3 of the second pixel column PXL2 on the other side (e.g., the right side of FIG. 21) of the first direction DR1.

Further, the fourth sub-pixel SP483 that is the other part of the intersection column CPL may be adjacent to the fourth sub-pixel SP481 of the third pixel column PXL3 in the first direction DR1.

Accordingly, each fourth sub-pixel SP483 that is the other part of the intersection column CPL corresponding to the third pixel column PXL3 may be provided between the first sub-pixel SP1 of the first pixel column PXL1 and the third sub-pixel SP3 of the second pixel column PXL2 in a first diagonal direction intersecting the first direction DR1 and the second direction DR2, and may be provided between the second sub-pixel SP2 of the first pixel column PXL1 and the second sub-pixel SP2 of the second pixel column PXL2 in a second diagonal direction perpendicular to the first diagonal direction.

Each of the fourth sub-pixels SP482 and SP483 of the intersection column CPL may have the first width W11 in the first direction DR1.

Each fourth sub-pixel SP482 that is a part of the intersection column CPL that corresponds to the first pixel column PXL1 and the second pixel column PXL2 may have the fourth width W22 greater than twice the third width W21 in the second direction DR2.

Each fourth sub-pixel SP483 that is the other part of the intersection column CPL that corresponds to the third pixel column PXL3 may have the third width W21 in the second direction DR2.

In accordance with the eighth example A8, there may be provided a plurality of pixels PX, each including seven sub-pixels adjacent to each other in the first direction DR1 or the second direction DR2 among the plurality of sub-pixels SPX. Each of the plurality of pixels PX includes at least one first sub-pixel SP1, at least one second sub-pixel SP2, at least one third sub-pixel SP3, and at least one fourth sub-pixel to serve as the basic unit for displaying various colors including the fourth color.

For example, each of the plurality of pixels PX according to the eighth example A8 may include one first sub-pixel SP1 and one second sub-pixel SP2 adjacent to each other in the first pixel column PXL1, one third sub-pixel SP3 and one second sub-pixel SP2 adjacent to each other in the second pixel column PXL2, one fourth sub-pixel SP481 in the third pixel columns PXL3, one fourth sub-pixel SP482 that is a part of the intersection column CPL, and one fourth sub-pixel SP483 that is the other part of the intersection column CPL.

Accordingly, compared to the second example A2, each pixel PX further includes one fourth sub-pixel SP482 that is a part of the intersection column CPL and one fourth sub-pixel SP483 that is the other part of the intersection column CPL, so that the brightness of the light of the fourth color may be improved.

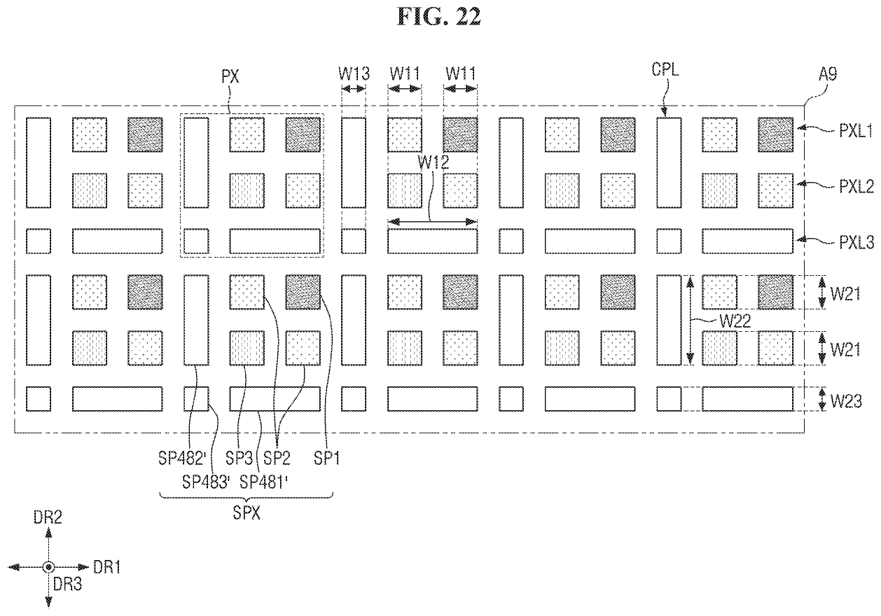

FIG. 22 is a plan view showing a ninth example of part A of FIG. 2.

Referring to FIG. 22, the arrangement pattern of the plurality of sub-pixels SPX according to a ninth example A9 is the same as that according to the eighth example A8 shown in FIG. 21, except that a fourth sub-pixel SP481′ of the third pixel column PXL3 has a fifth width W23 smaller than the third width W21 in the second direction DR2, and a fourth sub-pixel SP482′ that is a part of the intersection column CPL that corresponds to the first pixel column PXL1 and the second pixel column PXL2 has a sixth width W13 smaller than the first width W11 in the first direction DR1. Redundant descriptions will not be provided.

Here, fourth sub-pixels SP483′ that is the other part of the intersection column CPL that corresponds to the third pixel column PXL3 may have the sixth width W13 in the first direction DR1, and may have the fifth width W23 in the second direction DR2.

In accordance with the ninth example A9, compared to the eighth example A8, the widths of the fourth sub-pixels SP481′, SP482′, and SP483′ are reduced, so that the decrease in the widths of the first sub-pixel SP1, the second sub-pixel SP2, and the third sub-pixel SP3 may be suppressed.

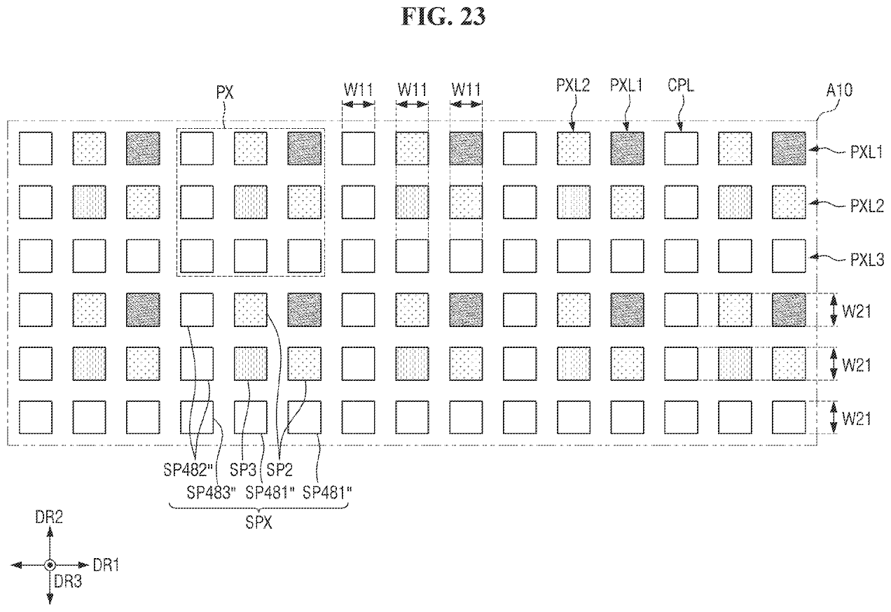

FIG. 23 is a plan view showing a tenth example of part A of FIG. 2.

Referring to FIG. 23, the arrangement pattern of the plurality of sub-pixels SPX according to the tenth example is the same as that according to the eight example A8 shown in FIG. 21 except that a fourth sub-pixel SP481″ of the third pixel column PXL3 has the first width W11 in the first direction DR1, and a fourth sub-pixel SP482″ that is a part of the intersection column CPL that corresponds to the first pixel column PXL1 and the second pixel column PXL2 have the second width W21 in the second direction DR2, and redundant descriptions will not be provided.

In accordance with the tenth example A10, the fourth sub-pixel SP481″ of the third pixel column PXL3 may be adjacent to any one of the second sub-pixel SP2 and the third sub-pixel SP3 of the second pixel column PXL2 on one side (e.g., the upper side of FIG. 23) of the second direction DR2, and may be adjacent to any one of the first sub-pixel SP1 and the second sub-pixel SP2 of the first pixel column PXL1 on the other side (e.g., the lower side of FIG. 23) of the second direction DR2.

Further, the fourth sub-pixels SP482″ that is a part of the intersection column CPL may be adjacent to any one of the first sub-pixel SP1 of the first pixel column PXL1 and the second sub-pixel SP2 of the second pixel column PXL2 on one side (e.g., the left side of FIG. 23) of the first direction DR1.

The fourth sub-pixel SP483″ that is the other part of the intersection column CPL may be adjacent to the fourth sub-pixel SP481″ of the third pixel column PXL3 in the first direction DR1.

Accordingly, each pixel PX includes five fourth sub-pixels SP481″, SP482″, and SP483″ having the same width, so that the grayscale expression of the light of the fourth color may be more variously or suitably divided.

However, the aspects of the disclosure are not restricted to the one set forth herein. The above and other aspects of the disclosure will become more apparent to one of daily skill in the art to which the disclosure pertains by referencing the claims, with functional equivalents thereof to be included therein.

What is claimed is:

1. A display device comprising:
a substrate comprising a display area comprising a plurality of sub-pixels;
a plurality of light emitting units on the substrate, the plurality of light emitting units respectively corresponding to the plurality of sub-pixels; and
a partition wall on the substrate and corresponding to a boundary between adjacent ones of the plurality of sub-pixels,
wherein the plurality of sub-pixels comprises a first sub-pixel corresponding to light of a first color, a second sub-pixel corresponding to light of a second color different from the first color, a third sub-pixel corresponding to light of a third color different from the first color and the second color, and a fourth sub-pixel corresponding to light of a fourth color having a wavelength band wider than wavelength bands of the first color, the second color, and the third color, and
each light emitting unit of the plurality of light emitting units comprises a light emitting element and a light adjustment layer covering the light emitting element, and the partition wall is around the light emitting unit.

2. The display device of claim 1, wherein the plurality of light emitting units comprise:
a first light emitting unit corresponding to the first sub-pixel and configured to emit the light of the first color;
a second light emitting unit corresponding to the second sub-pixel and configured to emit the light of the second color;
a third light emitting unit corresponding to the third sub-pixel and configured to emit the light of the third color; and
a fourth light emitting unit corresponding to the fourth sub-pixel and configured to emit the light of the fourth color,
wherein the first light emitting unit comprises a first light emitting element configured to emit the light of the first color, the second light emitting unit comprises a second light emitting element configured to emit the light of the second color, the third light emitting unit comprises a third light emitting element configured to emit the light of the third color, and the fourth light emitting unit comprises the third light emitting element.

3. The display device of claim 2, wherein the fourth light emitting unit further comprises a phosphor of a fifth color dispersed in the light adjustment layer,
the fifth color corresponds to a wavelength band between a wavelength band of the first color and a wavelength band of the second color, and
the phosphor of the fifth color is configured to convert a part of the light of the third color emitted from the third light emitting element into light of the fifth color.

4. The display device of claim 3, wherein the phosphor of the fifth color is at least one of (Y,Gd)₃(Al,Ga)₅O₁₂:Ce³⁺ and (Lu,Y)₃(Al,Ga)₅O₁₂:Ce³⁺.

5. The display device of claim 3, wherein the fourth light emitting unit further comprises a phosphor of the first color dispersed in the light adjustment layer together with the phosphor of the fifth color, and
the phosphor of the first color is configured to convert a part of the light of the third color emitted from the third light emitting element into the light of the first color.

6. The display device of claim 5, wherein the phosphor of the fifth color is at least one of (Y, Gd)₃(Al,Ga)₅O₁₂:Ce³⁺ and (Lu,Y)₃(Al,Ga)₅O₁₂:Ce³⁺, and
the phosphor of the first color is (Sr, Ca)AlSiN₃:Eu²⁺.

7. The display device of claim 5, wherein the fourth light emitting unit further comprises a phosphor of the second color dispersed in the light adjustment layer together with the phosphor of the fifth color and the phosphor of the first color, and
the phosphor of the second color is configured to convert a part of the light of the third color emitted from the third light emitting element into the light of the second color.

8. The display device of claim 7, wherein the phosphor of the fifth color is at least one of (Y, Gd)₃(Al,Ga)₅O₁₂:Ce³⁺, (Lu,Y)₃(Al,Ga)₅O₁₂:Ce³⁺, (Sr, Ba, Mg)SiO₄:Eu²⁺, and (Sr, Ba, Mg)SiO₂N₂:Eu²⁺,
the phosphor of the first color is at least one of (Sr, Ca)AlSiN₃:Eu²⁺, K₂SiF₆:Mn⁴⁺, Na₂SiF₆:Mn⁴⁺, KNaSiF₆:Mn⁴⁺, K₂GeF₆:Mn⁴⁺, K₂TiF₆:Mn⁴⁺, Mg₄GeO₃F:Mn⁴⁺, 3.5MgO·0.5MgF₂·GeO₂:Mn⁴⁺, Sr(Li₂Al₂O₂N₂):Eu²⁺, (Sr, Ba)₂Si₅N₈:Eu²⁺, BaMgAl₁₀O₁₇:Mn⁴⁺, Mg²⁺, CaS:Eu²⁺, InP, and CsPbI₃, and
the phosphor of the second color is at least one of (Sr, Ba, Mg)₂SiO₄:Eu²⁺, Lu₃(Al,Ga)₅O₁₂:Ce³⁺, Ba₃Si₆O₁₂N₂:Eu²⁺, SrGa₂S₄:Eu²⁺, Gamma AlON:Eu²⁺, InP, and CsPbBrs.

9. The display device of claim 8, wherein the fourth light emitting unit further comprises a phosphor of a sixth color dispersed in the light adjustment layer together with the phosphor of the fifth color, the phosphor of the first color, and the phosphor of the second color, the sixth color corresponds to a wavelength band between a wavelength band of the first color and a wavelength band of the fifth color, and
the phosphor of the sixth color is configured to convert a part of the light of the third color emitted from the third light emitting element into light of the sixth color.

10. The display device of claim 9, wherein the phosphor of the sixth color is at least one of Alpha-SiAlON and Sr₃SiO₅:Eu²⁺.

11. The display device of claim 2, wherein the fourth light emitting unit further comprises a phosphor of the first color and a phosphor of the second color dispersed in the light adjustment layer,
the phosphor of the first color is configured to convert a part of the light of the third color emitted from the third light emitting element into the light of the first color, and
the phosphor of the second color is configured to convert a part of the light of the third color emitted from the third light emitting element into the light of the second color.

12. The display device of claim 11, wherein the phosphor of the first color is (Sr, Ca)AlSiN₃:Eu²⁺, and
the phosphor of the second color is at least one of Lu₃Al₅O₁₂:Ce³⁺ and Y₃(Al, Ga)₅O₁₂:Ce³⁺.

13. The display device of claim 12, wherein the fourth light emitting unit further comprises a phosphor of a seventh color dispersed in the light adjustment layer together with the phosphor of the first color and the phosphor of the second color, the seventh color corresponds to a wavelength band between a wavelength band of the second color and a wavelength band of the third color, and
the phosphor of the seventh color is configured to convert a part of the light of the third color emitted from the third light emitting element into light of the seventh color.

14. The display device of claim 13, wherein the phosphor of the first color is at least one of (Sr, Ca)AlSiN₃:Eu²⁺ and K₂SiF₆:Mn⁴⁺,
the phosphor of the second color is at least one of Lu₃Al₅O₁₂:Ce³⁺ and Y₃(Al, Ga)₅O₁₂:Ce³⁺, and
the phosphor of the seventh color is at least one of (Ba, Mg)Si₂O₂N₂:Eu²⁺ and (Ba, Mg)₃Si₆O₃N₈:Eu²⁺.

15. The display device of claim 1, wherein the plurality of light emitting units comprise:
a first light emitting unit corresponding to the first sub-pixel and configured to emit the light of the first color;
a second light emitting unit corresponding to the second sub-pixel and configured to emit the light of the second color;
a third light emitting unit corresponding to the third sub-pixel and configured to emit the light of the third color; and
a fourth light emitting unit corresponding to the fourth sub-pixel and configured to emit the light of the fourth color,
wherein the light emitting element of each of the first light emitting unit, the second light emitting unit, the third light emitting unit, and the fourth light emitting unit is configured to emit the light of the third color,
the first light emitting unit further comprises a phosphor of the first color dispersed in a light adjustment layer of the first light emitting unit and configured to convert at least a part of the light of the third color emitted from the light emitting element into the light of the first color,
the second light emitting unit further comprises a phosphor of the second color dispersed in a light adjustment layer of the second light emitting unit and configured to convert at least a part of the light of the third color emitted from the light emitting element into the light of the second color,
the fourth light emitting unit further comprises a phosphor of a fifth color dispersed in a light adjustment layer of the fourth light emitting unit,
the fifth color corresponds to a wavelength band between a wavelength band of the first color and a wavelength band of the second color, and
the phosphor of the fifth color configured to convert a part of the light of the third color emitted from the light emitting element into light of the fifth color.

16. The display device of claim 1, wherein the plurality of light emitting units comprise:
a first light emitting unit corresponding to the first sub-pixel and configured to emit the light of the first color;
a second light emitting unit corresponding to the second sub-pixel and configured to emit the light of the second color;
a third light emitting unit corresponding to the third sub-pixel and configured to emit the light of the third color; and
a fourth light emitting unit corresponding to the fourth sub-pixel and configured to emit the light of the fourth color,
wherein the light emitting element of each of the first light emitting unit, the second light emitting unit, the third light emitting unit, and the fourth light emitting unit configured to emit light of a wavelength band lower than a wavelength band of the third color,
the first light emitting unit further comprises a phosphor of the first color dispersed in a light adjustment layer of the first light emitting unit and configured to convert at least a part of light emitted from the light emitting element into the light of the first color,
the second light emitting unit further comprises a phosphor of the second color dispersed in a light adjustment layer of the second light emitting unit and configured to convert at least a part of the light emitted from the light emitting element into the light of the second color,
the third light emitting unit further comprises a phosphor of the third color dispersed in a light adjustment layer of the third light emitting unit and configured to convert at least a part of the light emitted from the light emitting element into the light of the third color,
the fourth light emitting unit further comprises the phosphor of the first color, the phosphor of the second color, and the phosphor of the third color dispersed in a light adjustment layer of the fourth light emitting unit,
the phosphor of the first color is at least one of Mg₄GeO₃F:Mn⁴⁺, 3.5MgO·0.5MgF₂·GeO₂:Mn⁴⁺, K₂(Si, Ge, Ti)SiF₆:Mn⁴⁺, and (Sr, Ca)AlSiN₃:Eu²⁺,
the phosphor of the second color is at least one of Beta-SiAlON:Eu²⁺, SrGa₂S₄:Eu²⁺, BaAlMg₁₀O₁₇:Eu²⁺, Mn²⁺, (Sr, Ba, Mg)₂SiO₄:Eu²⁺, and (Lu,Y)₃(Al, Ga)₅O₁₂:Ce³⁺, and
the phosphor of the third color is BaAlMg₁₀O₁₇:Eu²⁺.

17. The display device of claim 16, wherein the fourth light emitting unit further comprises a phosphor of a fifth color and a phosphor of a sixth color dispersed in the light adjustment layer,
the fifth color corresponds to a wavelength band between a wavelength band of the first color and a wavelength band of the second color,
the phosphor of the fifth color configured to convert a part of light emitted from the light emitting element into light of the fifth color,
the sixth color corresponds to a wavelength band between a wavelength band of the first color and a wavelength band of the fifth color,
the phosphor of the sixth color configured to convert a part of the light emitted from the light emitting element into light of the sixth color,
the phosphor of the fifth color is at least one of (Y, Gd)₃(Al,Ga)₅O₁₂:Ce³⁺ and (Lu,Y)₃(Al,Ga)₅O₁₂:Ce³⁺, and
the phosphor of the sixth color is at least one of Alpha-SiAlON and Sr₃SiO₅:Eu²⁺.

18. The display device of claim 1, wherein an arrangement pattern of the plurality of sub-pixels comprises:
a first pixel column in which the first sub-pixel, the fourth sub-pixel, the third sub-pixel, and the fourth sub-pixel are repeatedly arranged in a first direction; and
a second pixel column which alternates with the first pixel column in a second direction intersecting the first direction, and in which the second sub-pixel and the fourth sub-pixel are repeatedly arranged in the first direction,
wherein in the second direction, each of the first sub-pixel of the first pixel column and the third sub-pixel of the first pixel column is adjacent to the fourth sub-pixel of the second pixel column, and
in the second direction, the second sub-pixel of the second pixel column is adjacent to the fourth sub-pixel of the first pixel column.

19. The display device of claim 18, wherein four sides of each of the first sub-pixel, the second sub-pixel, and the third sub-pixel are adjacent to the fourth sub-pixel.

20. The display device of claim 18 comprising a plurality of pixels each comprising eight sub-pixels adjacent to each other in the first direction and/or the second direction among the plurality of sub-pixels, and
each of the plurality of pixels comprises:
one first sub-pixel, one third sub-pixel, and two fourth sub-pixels adjacent to each other in the first pixel column; and
two second sub-pixels and two fourth sub-pixels adjacent to each other in the second pixel column.

21. The display device of claim 1, wherein an arrangement pattern of the plurality of sub-pixels comprises:
a first pixel column in which the first sub-pixel and the second sub-pixel are alternately arranged side by side in a first direction;
a second pixel column in which the second sub-pixel and the third sub-pixel are alternately arranged side by side in the first direction; and
a third pixel column in which the fourth sub-pixels are arranged side by side in the first direction,
in a second direction intersecting the first direction, the first pixel column and the second pixel column are adjacent to each other,
in the second direction, the first sub-pixel of the first pixel column is adjacent to the second sub-pixel of the second pixel column, and the third sub-pixel of the second pixel column is adjacent to the second sub-pixel of the first pixel column, and
in the second direction, the third pixel column is between one side of the first pixel column and another side of the second pixel column.

22. The display device of claim 21, wherein the fourth sub-pixel of the third pixel column is adjacent to one second sub-pixel and one third sub-pixel of the second pixel column on one side of the second direction, and is adjacent to one first sub-pixel and one second sub-pixel of the first pixel column on another side of the second direction,
each of the first sub-pixel, the second sub-pixel, and the third sub-pixel has a first width in the first direction, and
the fourth sub-pixel of the third pixel column has a second width in the first direction, the second width being greater than twice the first width.

23. The display device of claim 22, wherein the first sub-pixel, the second sub-pixel, and the third sub-pixel have a third width in the second direction, and
the fourth sub-pixel of the third pixel column has a fourth width in the second direction, the fourth width being smaller than the third width.

24. The display device of claim 22 comprising a plurality of pixels each comprising five sub-pixels adjacent to each other in the first direction and/or the second direction among the plurality of sub-pixels,
each of the plurality of pixels comprises:
one first sub-pixel and one second sub-pixel adjacent to each other in the first pixel column;
one third sub-pixel and one second sub-pixel adjacent to each other in the second pixel column; and
one fourth sub-pixel in the third pixel column.

25. The display device of claim 21, wherein the fourth sub-pixel of the third pixel column is adjacent to any one of the second sub-pixel and the third sub-pixel of the second pixel column on one side of the second direction, and is adjacent to any one of the first sub-pixel and the second sub-pixel of the first pixel column on another side of the second direction, and
the first sub-pixel, the second sub-pixel, the third sub-pixel, and the fourth sub-pixel have the same width in the first direction.

26. The display device of claim 25 comprising a plurality of pixels each comprising six sub-pixels adjacent to each other in the first direction and/or the second direction among the plurality of sub-pixels,
each of the plurality of pixels comprises:
one first sub-pixel and one second sub-pixel adjacent to each other in the first pixel column;
one third sub-pixel and one second sub-pixel adjacent to each other in the second pixel column; and
two fourth sub-pixels in the third pixel column.

27. The display device of claim 21, wherein the arrangement pattern of the plurality of sub-pixels further comprises an intersection column in which the fourth sub-pixels are arranged side by side in the second direction,
the fourth sub-pixel corresponding to the first pixel column and the second pixel column in a first part of the intersection column is adjacent to at least one of the first sub-pixel of the first pixel column and the second sub-pixel of the second pixel column on one side of the first direction, and is adjacent to at least one of the second sub-pixel of the first pixel column and the third sub-pixel of the second pixel column on another side of the first direction, and
the fourth sub-pixel corresponding to the third pixel column in a second part of the intersection column is adjacent to the fourth sub-pixel of the third pixel column in the first direction.

28. The display device of claim 27, wherein the fourth sub-pixel in the first part of the intersection column is between the first sub-pixel of the first pixel column and the third sub-pixel of the second pixel column in a first diagonal direction intersecting the first direction and the second direction, and is between the second sub-pixel of the first pixel column and the second sub-pixel of the second pixel column in a second diagonal direction perpendicular to the first diagonal direction.

29. The display device of claim 27, wherein the fourth sub-pixel of the third pixel column is adjacent to the first sub-pixel and the second sub-pixel of the first pixel column on the other side of the second direction, and is adjacent to the second sub-pixel and the third sub-pixel of the second pixel column on the one side of the second direction,
the fourth sub-pixel in the first part of the intersection column is adjacent to sub-pixels in the first pixel column and the second pixel column in the first direction,
the fourth sub-pixel in the second part of the intersection column is adjacent to sub-pixels in the third pixel column in the first direction,
each of the first sub-pixel, the second sub-pixel, and the third sub-pixel has a first width in the first direction,
the fourth sub-pixel of the third pixel column has a second width greater than twice the first width in the first direction,
each of the first sub-pixel, the second sub-pixel, and the third sub-pixel has a third width in the second direction, and
the fourth sub-pixel in the first part of the intersection column has a fourth width greater than twice the third width.

30. The display device of claim 29, wherein the fourth sub-pixel in the second part of the intersection column has the first width in the first direction and has the third width in the second direction.

31. The display device of claim 29, wherein the fourth sub-pixel of the third pixel column has a fifth width smaller than the third width in the second direction,
the fourth sub-pixel in the first part of the intersection column has a sixth width smaller than the first width in the first direction, and
the fourth sub-pixel in the second part of the intersection column has the sixth width in the first direction and has the fifth width in the second direction.

32. The display device of claim 29 comprising a plurality of pixels each comprising seven sub-pixels adjacent to each other in the first direction and/or the second direction among the plurality of sub-pixels,
each of the plurality of pixels comprises:
one first sub-pixel and one second sub-pixel adjacent to each other in the first pixel column;
one third sub-pixel and one second sub-pixel adjacent to each other in the second pixel column;
one fourth sub-pixel in the third pixel column;
one fourth sub-pixel in the first part of the intersection column; and
one fourth sub-pixel in the second part of the intersection column.

33. The display device of claim 27, wherein the fourth sub-pixel of the third pixel column is adjacent to any one of the first sub-pixel of the first pixel column and the second sub-pixel of the second pixel column on one side of the second direction, and is adjacent to any one of the second sub-pixel of the first pixel column and the third sub-pixel of the second pixel column on the other side of the second direction,
the fourth sub-pixel in the first part of the intersection column is adjacent to any one of the first sub-pixel of the first pixel column and the second sub-pixel of the second pixel column on one side of the first direction, and is adjacent to any one of the second sub-pixel of the first pixel column and the third sub-pixel of the second pixel column on the other side of the first direction, and
the first sub-pixel, the second sub-pixel, the third sub-pixel, and the fourth sub-pixel have the same width in each of the first direction and the second direction.

34. The display device of claim 33 comprising a plurality of pixels each comprising nine sub-pixels adjacent to each other in the first direction and/or the second direction among the plurality of sub-pixels,
each of the plurality of pixels comprises:
one first sub-pixel and one second sub-pixel adjacent to each other in the first pixel column;
one third sub-pixel and one second sub-pixel adjacent to each other in the second pixel column;
two fourth sub-pixels in the third pixel column;
two fourth sub-pixels in the first part of the intersection column; and
one fourth sub-pixel in the second part of the intersection column.
